(19) United States
(12) Patent Application Publication
(10) Pub. No.: US 2024/0224469 A1
(43) Pub. Date: Jul. 4, 2024

(54) VAPOR CHAMBER, WICK SHEET FOR VAPOR CHAMBER, AND ELECTRONIC APPARATUS

(71) Applicant: DAI NIPPON PRINTING CO., LTD., Tokyo-to (JP)

(72) Inventors: Kazunori ODA, Tokyo-to (JP); Shinichiro TAKAHASHI, Tokyo-to (JP); Takayuki OTA, Tokyo-to (JP); Makoto YAMAKI, Tokyo-to (JP); Youji KOZURU, Tokyo-to (JP); Toshihiko TAKEDA, Tokyo-to (JP)

(73) Assignee: DAI NIPPON PRINTING CO., LTD., Tokyo-to (JP)

(21) Appl. No.: 18/288,603

(22) PCT Filed: Apr. 21, 2022
(86) PCT No.: PCT/JP2022/018383

§ 371 Date: Oct. 27, 2023

(30) Foreign Application Priority Data
Apr. 27, 2021 (JP) 2021-075258
May 7, 2021 (JP) 2021-079151
Jul. 20, 2021 (JP) 2021-119907
Mar. 9, 2022 (WO) PCT/JP2022/010293

(51) Int. Cl. H05K 7/20

(52) U.S. Cl. CPC H05K 7/20336

(57) ABSTRACT

A wick sheet for a vapor chamber includes a first main body surface, second main body surface, frame, and plurality of lands. A vapor passage that extends through from the first main body surface to the second main body surface. The vapor passage through which vapor of a working fluid passes is formed. A liquid channel that communicates with the vapor passage and through which a liquid working fluid passes is formed on the second main body surface side of the lands. An end of the vapor passage in an extension direction is in contact with at least one land, and a first main body surface-side channel that communicates with the vapor passage is formed in a connection region that is on the first main body surface side of the land and in which the end of the vapor passage in the extension direction is in contact with the land.

### TECHNICAL FIELD

The present disclosure relates to a vapor chamber, a wick sheet for a vapor chamber, and an electronic apparatus.

### BACKGROUND ART

Central processing units (CPUs), light emitting diodes (LEDs), power semiconductors, and the like that are used for mobile terminals and the like, including portable terminals and tablet terminals, are devices accompanied by heat generation. Devices accompanied by heat generation are cooled by heat dissipation members, such as heat pipes. In recent years, for the purpose of providing thinner mobile terminals and the like, low-profile heat dissipation members are also desired. For this reason, development of vapor chambers that can lead to a further lower profile than heat pipes has been proceeding. A working fluid is filled in vapor chambers. The working fluid absorbs and dissipates the heat of devices to cool the devices. For example, PTL 1 describes a sheet heat pipe in which two or more metal foil sheets are laminated.

More specifically, a working fluid in the vapor chamber receives heat from a device at a part proximate to the device (vaporizing portion) to vaporize into vapor (working vapor). The working vapor diffuses in a direction away from the vaporizing portion in a vapor channel to be cooled and condensed into liquid. A liquid channel serving as a capillary structure (wick) is provided in the vapor chamber. A working fluid (working liquid) condensed into liquid enters the liquid channel from the vapor channel, flows through the liquid channel, and is transferred toward the vaporizing portion. Then, the working liquid receives heat at the vaporizing portion again to vaporize. In this way, the working fluid transfers heat of the device by circulating in the vapor chamber while repeating a phase change, that is, vaporization and condensation, thus enhancing heat dissipation efficiency.

### CITATION LIST

### Patent Literature

PTL 1: Japanese Unexamined Patent Application Publication No. 2016-017702

The present embodiment provides a vapor chamber, a wick sheet for a vapor chamber, and an electronic apparatus, capable of causing a working vapor to go around in a wide region in the vapor chamber. The present embodiment also provides a vapor chamber, a wick sheet for a vapor chamber, and an electronic apparatus, capable of causing heat from a heat source to go around uniformly in a plane of the vapor chamber.

### SUMMARY OF INVENTION

A wick sheet according to the present embodiment is a wick sheet for a vapor chamber. The wick sheet includes a first main body surface, a second main body surface on an opposite side to the first main body surface, a frame, and a plurality of lands provided inside the frame so as to be spaced apart from each other. A vapor passage extending through from the first main body surface to the second main body surface and through which vapor of a working fluid passes is formed between the frame and the land or between the plurality of lands. A liquid channel that communicates with the vapor passage and through which the liquid working fluid passes is formed on the second main body surface side of at least one of the lands. An end of the vapor passage in an extension direction is in contact with at least one of the plurality of lands, and a first main body surface-side channel that communicates with the vapor passage is formed on the first main body surface side of the land in a connection region in which the end of the vapor passage in the extension direction is in contact with the land.

### BRIEF DESCRIPTION OF DRAWINGS

FIG. 1 is a schematic perspective view illustrating an electronic apparatus according to a first embodiment.

FIG. 2 is a top view showing a vapor chamber according to the first embodiment.

FIG. 3 is a sectional view of the vapor chamber, taken along the line Ill-Ill in FIG. 2.

FIG. 4 is a top view of a wick sheet of FIG. 3.

FIG. 5 is a bottom view of the wick sheet of FIG. 3.

FIG. 6 is a sectional view of the vapor chamber, taken along the line VI-VI in FIG. 2.

FIG. 7 is a partially enlarged top view of a liquid channel shown in FIG. 4.

FIG. 8 is a partially enlarged bottom view of a first main body surface-side channel shown in FIG. 5.

FIG. 9 is an enlarged bottom view (an enlarged view of portion VIII in FIG. 5) showing an area around connection regions of the wick sheet.

FIGS. 10(a) to 10(c) are views illustrating a manufacturing method for the vapor chamber according to the first embodiment.

FIG. 11 is an enlarged bottom view showing an area around a connection region of a wick sheet according to a first modification of the first embodiment.

FIG. 12 is an enlarged bottom view showing an area around a connection region of a wick sheet according to a second modification of the first embodiment.

FIG. 13 is an enlarged bottom view showing an area around a connection region of a wick sheet according to a third modification of the first embodiment.

FIG. 14 is an enlarged bottom view showing an area around a connection region of a wick sheet according to a fourth modification of the first embodiment.

FIG. 15 is an enlarged bottom view showing an area around a connection region of a wick sheet according to a fifth modification of the first embodiment.

FIGS. 16(a) and 16(b) are enlarged bottom views showing an area around the connection region of the wick sheet according to the fifth modification of the first embodiment.

FIGS. 17(a) and 17(b) are enlarged bottom views showing an area around the connection region of the wick sheet according to the fifth modification of the first embodiment.

FIGS. 18(a) to 18(c) are sectional views (sectional views taken along the line XVIII-XVIII in FIGS. 15 to 17) in an area around the connection region of the wick sheet according to the fifth modification of the first embodiment.

FIG. 19 is a schematic perspective view illustrating an electronic apparatus according to a second embodiment.

FIG. 20 is a top view showing a vapor chamber according to the second embodiment.

FIG. 21 is a sectional view of the vapor chamber, taken along the line XXI-XXI in FIG. 20.

FIG. 22 is a top view of a wick sheet according to the second embodiment.

FIG. 23 is a bottom view of the wick sheet according to the second embodiment.

FIG. 24 is a partially enlarged top view of a liquid channel shown in FIG. 22.

FIGS. 25(a) and 25(b) are schematic top views showing the wick sheet.

FIGS. 26(a) to 26(c) are top views showing the flow of working fluid in the wick sheet.

FIG. 27 is a top view showing a wick sheet according to a first modification of the second embodiment.

FIGS. 28(a) and 28(b) are top views showing a wick sheet according to a second modification of the second embodiment.

FIGS. 29(a) and 29(b) are top views showing a wick sheet according to a third modification of the second embodiment.

FIGS. 30(a) to 30(c) are top views showing a wick sheet according to a fourth modification of the second embodiment.

FIGS. 31(a) and 31(b) are top views showing a wick sheet according to a fifth modification of the second embodiment.

FIG. 32 is a top view showing a wick sheet according to a sixth modification of the second embodiment.

FIG. 33 is a top view showing a wick sheet according to a seventh modification of the second embodiment.

FIG. 34 is a top view showing a wick sheet according to an eighth modification of the second embodiment.

FIG. 35 is a top view showing a wick sheet according to a ninth modification of the second embodiment.

FIGS. 36(a) to 36(c) are sectional views showing vapor chambers according to modifications of the second embodiment.

### DESCRIPTION OF EMBODIMENTS

According to a first aspect of the present disclosure, a wick sheet for a vapor chamber includes a first main body surface, a second main body surface on an opposite side to the first main body surface, a frame, and a plurality of lands provided inside the frame so as to be spaced apart from each other. A vapor passage extending through from the first main body surface to the second main body surface and through which vapor of a working fluid passes is formed between the frame and the land or between the plurality of lands. A liquid channel that communicates with the vapor passage and through which the liquid working fluid passes is formed on the second main body surface side of at least one of the lands. An end of the vapor passage in an extension direction is in contact with at least one of the plurality of lands, and a first main body surface-side channel that communicates with the vapor passage is formed on the first main body surface side of the land in a connection region in which the end of the vapor passage in the extension direction is in contact with the land.

According to a second aspect of the present disclosure, in the wick sheet according to the above-described first aspect, another vapor passage may be present on an opposite side of the connection region to a side where the end of the vapor passage in the extension direction is in contact with the land.

According to a third aspect of the present disclosure, in the wick sheet according to the above-described first aspect or second aspect, a vaporization region in which a heat source is disposed may be present on the wick sheet, and the first main body surface-side channel may be continuously formed up to the vaporization region along the land.

According to a fourth aspect of the present disclosure, in the wick sheet according to any one of the above-described first aspect to third aspect, the first main body surface-side channel may also be formed in another one of the lands extending along the vapor passage.

According to a fifth aspect of the present disclosure, in the wick sheet according to any one of the above-described first aspect to fourth aspect, in the connection region in which the end of the vapor passage in the extension direction is in contact with the land, the land and the vapor passage may intersect at an angle not a right angle in a plan view.

According to a sixth aspect of the present disclosure, in the wick sheet according to any one of the above-described first aspect to fifth aspect, the connection region may be located at a part where the land is curved.

According to a seventh aspect of the present disclosure, in the wick sheet according to any one of the above-described first aspect to sixth aspect, the vapor passage may have a shape that gradually narrows in width toward the end in the extension direction.

According to an eighth aspect of the present disclosure, in the wick sheet according to any one of the above-described first aspect to seventh aspect, at least two of the plurality of lands may merge, and the end of the vapor passage in the extension direction may be in contact with the land at the merged part.

According to a ninth aspect of the present disclosure, in the wick sheet according to any one of the above-described first aspect to fourth aspect, at a location where the end of the vapor passage in the extension direction is in contact with the land, the vapor passage and the land may be orthogonal to each other in a plan view.

According to a tenth aspect of the present disclosure, a vapor chamber filled with a working fluid includes a first sheet, a second sheet, and the wick sheet according to any one of the above-described first aspect to ninth aspect, interposed between the first sheet and the second sheet.

According to an eleventh aspect of the present disclosure, an electronic apparatus includes a housing, a device accommodated in the housing, and the vapor chamber according to the above-described tenth aspect, in thermal contact with the device.

According to the first aspect to the eleventh aspect of the present disclosure, it is possible to cause a working vapor to go around in a wide region in the vapor chamber.

According to a twelfth aspect of the present disclosure, a wick sheet for a vapor chamber includes a vapor passage through which vapor of a working fluid passes, and a liquid channel that communicates with the vapor passage and through which the liquid working fluid passes. A first heat source region in which a first heat source is disposed and a second heat source region in which a second heat source is disposed are disposed on the wick sheet. The first heat source region and the second heat source region are connected to each other by at least one coupling vapor passage with a length less than or equal to twice a center-to-center distance between the first heat source region and the second heat source region, or connected to each other by at least one coupling liquid channel with a length less than or equal to twice the center-to-center distance between the first heat source region and the second heat source region.

According to a thirteenth aspect of the present disclosure, in the wick sheet according to the above-described twelfth aspect, the wick sheet is a wick sheet for a vapor chamber and includes a vapor passage through which vapor of a working fluid passes, and a liquid channel that communicates with the vapor passage and through which the liquid working fluid passes. A first heat source region in which a first heat source is disposed and a second heat source region in which a second heat source is disposed are disposed on the wick sheet. The first heat source region and the second heat source region are connected to each other by at least one coupling vapor passage and at least one coupling liquid channel.

According to a fourteenth aspect of the present disclosure, in the wick sheet according to the above-described twelfth aspect or thirteenth aspect, the vapor passage may include a sole vapor passage connected to any one of the first heat source region and the second heat source region and not connected to the other one of the first heat source region and the second heat source region.

According to a fifteenth aspect of the present disclosure, in the wick sheet according to any one of the above-described twelfth aspect to fourteenth aspect, the first heat source region and the second heat source region may be connected to each other by at least one coupling vapor passage, and the vapor passage may include a branched vapor passage connected midway to the coupling vapor passage.

According to a sixteenth aspect of the present disclosure, in the wick sheet according to any one of the above-described twelfth aspect to fifteenth aspect, the liquid channel may include a sole liquid channel connected to any one of the first heat source region and the second heat source region and not connected to the other one of the first heat source region and the second heat source region.

According to a seventeenth aspect of the present disclosure, in the wick sheet according to any one of the above-described twelfth aspect to sixteenth aspect, the first heat source region and the second heat source region may be connected to each other by at least one coupling liquid channel, and the liquid channel may include a branched liquid channel connected midway to the coupling liquid channel.

According to an eighteenth aspect of the present disclosure, in the wick sheet according to the above-described seventeenth aspect, the branched liquid channel may be curved at a connecting part with the coupling liquid channel, and a connecting recess with no liquid channel may be present at the connecting part of the branched liquid channel with the coupling liquid channel.

According to a nineteenth aspect of the present disclosure, in the wick sheet according to the above-described seventeenth aspect, the branched liquid channel may be curved at a connecting part with the coupling liquid channel, and a connecting liquid channel may be present at the connecting part of the branched liquid channel with the coupling liquid channel.

According to a twentieth aspect of the present disclosure, in the wick sheet according to any one of the above-described twelfth aspect to nineteenth aspect, a third heat source region in which a third heat source is disposed may be disposed on the wick sheet, and the third heat source region and the first heat source region or the second heat source region may be connected to each other by the at least one coupling vapor passage or the at least one coupling liquid channel.

According to a twenty-first aspect of the present disclosure, in the wick sheet according to any one of the above-described twelfth aspect to twentieth aspect, a third heat source region in which a third heat source is disposed may be disposed on the wick sheet, the second heat source region and the third heat source region may be connected to each other by the at least one coupling vapor passage or the at least one coupling liquid channel, and the third heat source region and the first heat source region may be connected to each other by the at least one coupling vapor passage and the at least one coupling liquid channel.

According to a twenty-second aspect of the present disclosure, in the wick sheet according to any one of the above-described twelfth aspect to twenty-first aspect, the vapor passage may include at least two branched vapor passages connected midway to the coupling vapor passage, and, of the at least two branched vapor passages, one of the branched vapor passages may extend outward in a plane direction of the wick sheet, and the other one of the branched vapor passages may extend inward in the plane direction of the wick sheet.

According to a twenty-third aspect of the present disclosure, a vapor chamber filled with a working fluid includes at least one sheet, and the wick sheet according to any one of the above-described twelfth aspect to twenty-second aspect, laminated on the sheet.

According to a twenty-fourth aspect of the present disclosure, a vapor chamber filled with a working fluid includes a vapor passage through which vapor of a working fluid passes, and a liquid channel that communicates with the vapor passage and through which the liquid working fluid passes. A first heat source region in which a first heat source is disposed and a second heat source region in which a second heat source is disposed are disposed. The first heat source region and the second heat source region are connected to each other by at least one coupling vapor passage with a length less than or equal to twice a center-to-center distance between the first heat source region and the second heat source region, or connected to each other by at least one coupling liquid channel with a length less than or equal to twice the center-to-center distance between the first heat source region and the second heat source region.

According to a twenty-fifth aspect of the present disclosure, a vapor chamber filled with a working fluid includes a vapor passage through which vapor of a working fluid passes, and a liquid channel that communicates with the vapor passage and through which the liquid working fluid passes. A first heat source region in which a first heat source is disposed and a second heat source region in which a second heat source is disposed are disposed. The first heat source region and the second heat source region are connected to each other by at least one coupling vapor passage and at least one coupling liquid channel.

According to a twenty-sixth aspect of the present disclosure, a housing, the first heat source and the second heat source accommodated in the housing, and the vapor chamber according to any one of the above-described twenty-third aspect to twenty-fifth aspect, in thermal contact with the first heat source and the second heat source.

According to the twelfth aspect to the twenty-sixth aspect of the present disclosure, it is possible to cause heat from the heat sources to go around uniformly in a plane of the vapor chamber.

### First Embodiment

Hereinafter, a first embodiment will be described with reference to the drawings. In the drawings attached to the present specification, for the sake of easiness of illustration and understanding, the scale, dimensional aspect ratio, and the like are changed or exaggerated as needed from those of real ones.

Terms, such as “parallel”, “orthogonal”, and “the same”, values of length, angle, and physical characteristics, and the like that determine shapes, geometrical conditions, physical characteristics, the degrees of them, used in the specification are not limited to strict meanings. These terms or numeric values are interpreted so as to include the range of degrees to which similar functions can be expected. Furthermore, in the drawings, for the sake of clear illustration, the shapes of a plurality of portions from which similar functions can be expected are shown regularly; however, the shapes of the portions may be different from each other without limitations to strict meanings within the range in which the functions can be expected. In the drawings, boundary lines each representing a joint surface or the like between members are indicated merely by straight lines for the sake of convenience. The boundary lines are not limited to strict straight lines. The shapes of the boundary lines can be selected within the range in which desired joint performance can be expected.

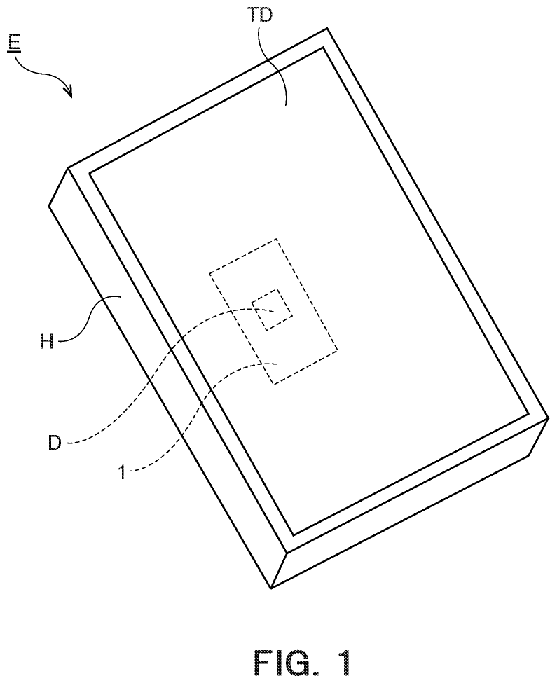

A vapor chamber, a wick sheet for a vapor chamber, and an electronic apparatus according to the present embodiment will be described with reference to FIGS. 1 to 9. A vapor chamber 1 according to the present embodiment is a device mounted on an electronic apparatus E to cool a device D serving as a heat source (heating element) accommodated in the electronic apparatus E. Examples of the device D include electronic devices (devices to be cooled) accompanied by heat generation, used in mobile terminals and the like, such as portable terminals and tablet terminals. Examples of the electronic device accompanied by heat generation include central processing units (CPUs), light emitting diodes (LEDs), and power semiconductors.

Here, initially, the electronic apparatus E on which the vapor chamber 1 according to the present embodiment is mounted will be described by taking a tablet terminal as an example. As shown in FIG. 1, the electronic apparatus E (for example, a tablet terminal) includes a housing H, the device D accommodated in the housing H, and the vapor chamber 1. In the electronic apparatus E shown in FIG. 1, a touch panel display TD is provided on the front face of the housing H. The vapor chamber 1 is accommodated in the housing H and is disposed in thermal contact with the device D. With this configuration, the vapor chamber 1 can receive heat that is generated in the device D during use of the electronic apparatus E. The heat received by the vapor chamber 1 is released to outside the vapor chamber 1 via working fluids 2a, 2b (described later). In this way, the device D is effectively cooled. When the electronic apparatus E is a tablet terminal, the device D corresponds to a central processing unit or the like.

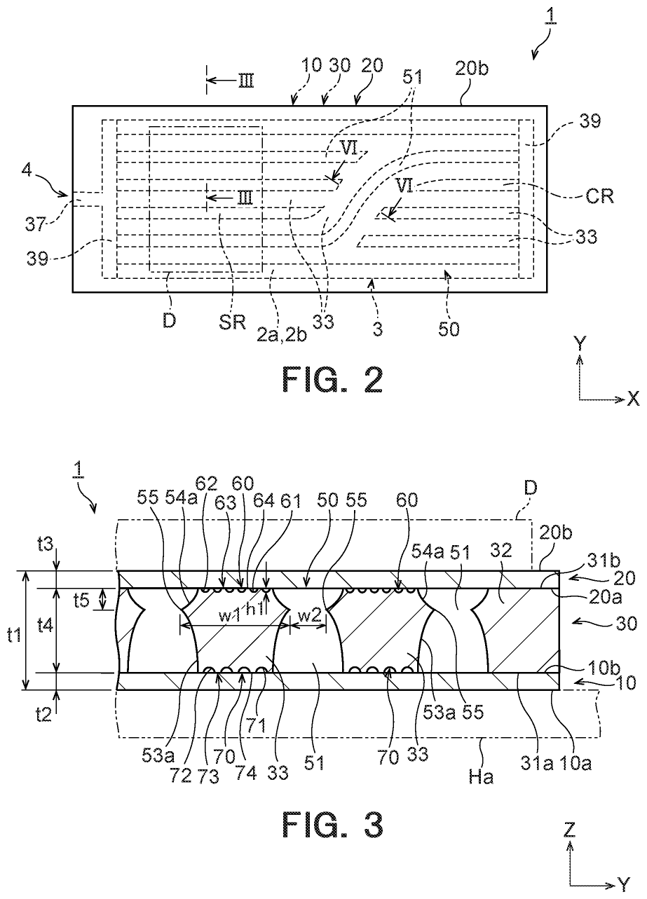

Next, the vapor chamber 1 according to the present embodiment will be described. As shown in FIGS. 2 and 3, the vapor chamber 1 has a sealed space 3 filled with the working fluids 2a, 2b. The vapor chamber 1 is configured such that, as the working fluids 2a, 2b in the sealed space 3 repeat a phase change, the device D of the above-described electronic apparatus E is effectively cooled. Examples of the working fluids 2a, 2b include pure water, ethanol, methanol, acetone, and mixed solutions of some of them. The working fluids 2a, 2b may have freezing and expansion properties. In other words, the working fluids 2a, 2b may be fluids that expand when frozen. Examples of the working fluids 2a, 2b having freezing and expansion properties include pure water and a solution with an additive, such as pure water and alcohol.

As shown in FIGS. 2 and 3, the vapor chamber 1 includes a lower sheet 10 (first sheet), an upper sheet 20 (second sheet), and a wick sheet for a vapor chamber (hereinafter, simply referred to as wick sheet 30). The wick sheet 30 is interposed between the lower sheet 10 and the upper sheet 20. In the vapor chamber 1 according to the present embodiment, the lower sheet 10, the wick sheet 30, and the upper sheet 20 are laminated in this order.

The vapor chamber 1 is schematically formed in a thin sheet shape. The planar shape of the vapor chamber 1 is selectable and may be a rectangular shape as shown in FIG. 2. The planar shape of the vapor chamber 1 may be, for example, a rectangular shape with one side having a length of greater than or equal to 50 mm and less than or equal to 200 mm and the other side having a length of greater than or equal to 150 mm and less than or equal to 600 mm or may be a square shape with one side having a length of greater than or equal to 70 mm and less than or equal to 300 mm. The plane dimensions of the vapor chamber 1 are selectable. In the present embodiment, in an example, an example in which the planar shape of the vapor chamber 1 is a rectangular shape having an X direction (described later) as a longitudinal direction will be described. In this case, as shown in FIG. 2, the lower sheet 10, the upper sheet 20, and the wick sheet 30 each may have a planar shape similar to that of the vapor chamber 1. The planar shape of the vapor chamber 1 is not limited to a rectangular shape and may be a selected shape, such as a circular shape, an elliptical shape, an L-shape, a T-shape, and a U-shape.

As shown in FIG. 2, the vapor chamber 1 has a vaporization region SR where the working fluids 2a, 2b vaporize and a condensation region CR where the working fluids 2a, 2b condense.

The vaporization region SR is a region that overlaps the device D that is a heat source in a plan view and is a region in which the device D is attached. The vaporization region SR may be disposed in a selected place of the vapor chamber 1. In the present embodiment, the vaporization region SR is formed on one side (left side in FIG. 2) of the vapor chamber 1 in the X direction. Heat from the device D is transferred to the vaporization region SR, and a liquid working fluid (referred to as working liquid 2b as needed) vaporizes in the vaporization region SR due to the heat. Heat from the device D can be transferred not only to the region that overlaps the device D but also to around the region in a plan view. For this reason, the vaporization region SR includes a region that overlaps the device D and a region therearound in a plan view. Here, a plan view is a state viewed in a direction orthogonal to a surface that the vapor chamber 1 receives heat from the device D (a second upper sheet surface 20b (described later) of the upper sheet 20) and a surface that releases the received heat (a first lower sheet surface 10a (described later) of the lower sheet 10). In other words, a plan view, for example, corresponds to a state when the vapor chamber 1 is viewed from above as shown in FIG. 2 or a state when the vapor chamber 1 is viewed from below.

The condensation region CR is a region that does not overlap the device D that is a heat source in a plan view and is a region where the working vapor 2a mainly releases heat to condense. The condensation region CR may also be referred to as a region around the vaporization region SR. Heat from the working vapor 2a is released to the lower sheet 10 in the condensation region CR, and the working vapor 2a is cooled in the condensation region CR to condense.

When the vapor chamber 1 is installed in a mobile terminal, an upper and lower relation can be lost depending on the posture of the mobile terminal. However, in the present embodiment, for the sake of convenience, a sheet that receives heat from the device D is referred to as the above-described upper sheet 20, and a sheet that releases the received heat is referred to as the above-described lower sheet 10. Therefore, the description will be made in a state where the lower sheet 10 is disposed on the lower side and the upper sheet 20 is disposed on the upper side.

As shown in FIG. 3, the lower sheet 10 has the first lower sheet surface 10a on an opposite side to the wick sheet 30 and a second lower sheet surface 10b on an opposite side to the first lower sheet surface 10a (that is, adjacent to the wick sheet 30). The lower sheet 10 may be formed entirely in a flat shape. The lower sheet 10 may entirely have a constant thickness. A housing member Ha that is part of the housing of the mobile terminal or the like is attached to the first lower sheet surface 10a The whole of the first lower sheet surface 10a may be covered with the housing member Ha.

As shown in FIG. 3, the upper sheet 20 has a first upper sheet surface 20a provided adjacent to the wick sheet 30 and the second upper sheet surface 20b on an opposite side to the first upper sheet surface 20a. The upper sheet 20 may be formed entirely in a flat shape. The upper sheet 20 may entirely have a constant thickness. The above-described device D is attached to the second upper sheet surface 20b.

As shown in FIG. 3, the wick sheet 30 includes a vapor channel 50, liquid channels 60 disposed adjacent to the vapor channel 50, and first main body surface-side channels 70 disposed on an opposite side to the liquid channels 60 in the thickness direction of the wick sheet 30. The wick sheet 30 has a first main body surface 31a and a second main body surface 31b on an opposite side to the first main body surface 31a. The first main body surface 31a is disposed adjacent to the lower sheet 10, and the second main body surface 31b is disposed adjacent to the upper sheet 20.

The second lower sheet surface 10b of the lower sheet 10 and the first main body surface 31a of the wick sheet 30 may be permanently joined with each other by diffusion joining. Similarly, the first upper sheet surface 20a of the upper sheet 20 and the second main body surface 31b of the wick sheet 30 may be permanently joined with each other by diffusion joining. The lower sheet 10, the upper sheet 20, and the wick sheet 30 may be joined not by diffusion joining but by another method, such as brazing, as long as they can be permanently joined. The term “permanently joined” is not limited to a strict meaning. The term “permanently joined” is used as a term meaning that a joint of the lower sheet 10 with the wick sheet 30 can be maintained and a joint of the upper sheet 20 with the wick sheet 30 can be maintained to such an extent that the sealability of the sealed space 3 can be maintained during operation of the vapor chamber 1.

As shown in FIGS. 3 to 5, the wick sheet 30 according to the present embodiment has the frame 32 formed in a rectangular frame shape in a plan view and lands 33 provided inside the frame 32. The frame 32 and the lands 33 are portions where the material of the wick sheet 30 is left without being removed by etching in an etching process (described later). In the present embodiment, the frame 32 is formed in a rectangular frame shape in a plan view; however, the configuration is not limited thereto. The frame 32 may have a selected frame shape, such as a circular frame shape, an elliptical frame shape, an L-frame shape, a T-frame shape, and a U-frame shape. The vapor channel 50 is defined inside the frame 32. In other words, the working vapor 2a flows inside the frame 32 and around the lands 33.

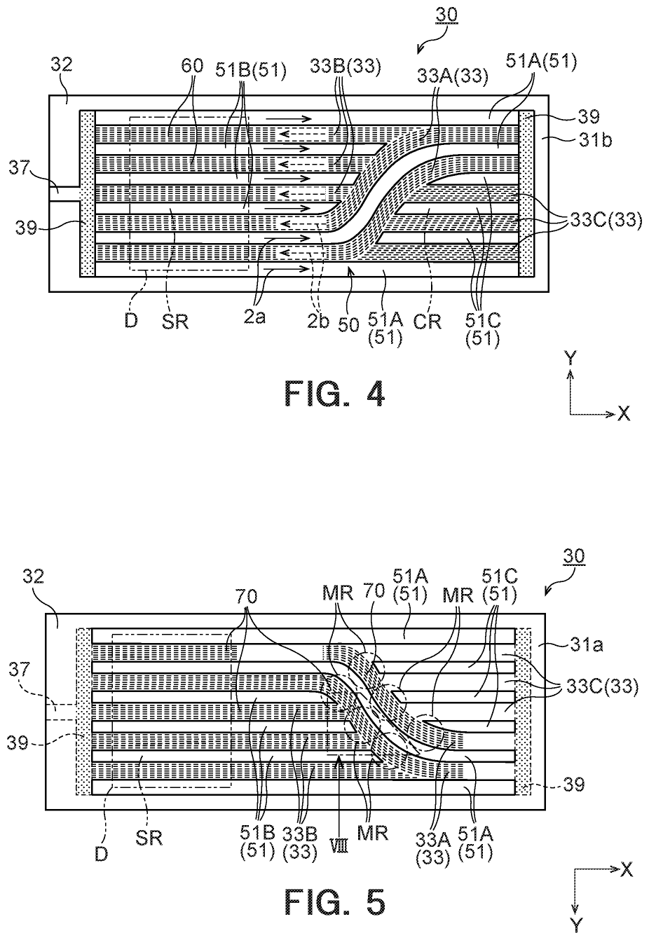

In the present embodiment, each of the lands 33 may extend in a long-slender shape in a plan view. The planar shape of each land 33 may be a selected shape, such as a long-slender rectangular shape, a curved shape, including a circular arc, a U-shape, and an S-shape, and a bent line shape, including a V-shape and an L-shape. In FIGS. 4 and 5, the plurality of lands 33 includes the lands extending in a straight line in the X direction (first direction) in a plan view (second lands 33B and third lands 33C), and the lands each made up of linear parts and a substantially S-curved part (first lands 33A). Each of the lands 33 may be disposed so as to be spaced apart from the other lands 33 in a width direction of the lands 33. A working vapor 2a is configured to flow around the lands 33 so as to be transferred toward the condensation region CR. Thus, interference with the flow of working vapor 2a is suppressed. The width w1 (see FIG. 3) of the land 33 may be, for example, greater than or equal to 30 μm and less than or equal to 3000 μm. Here, the width w1 of the land 33 is the dimension of the land 33 in a direction orthogonal to an extension direction of the land 33 (width direction) and means a dimension at a position where the land 33 is the widest (for example, a position where a protrusion 55 (described later) is present).

The frame 32 and the lands 33 are diffusion-joined to the lower sheet 10 and diffusion-joined to the upper sheet 20. Thus, the mechanical strength of the vapor chamber 1 is improved. First wall surfaces 53a and second wall surfaces 54a of vapor passages 51 (described later) are components of side walls of the lands 33. The first main body surface 31a and the second main body surface 31b of the wick sheet 30 may be formed in a flat shape over the frame 32 and the lands 33.

As shown in FIGS. 4 and 5, the plurality of lands 33 includes the first lands 33A, the second lands 33B, and the third lands 33C. Each of the first lands 33A, the second lands 33B, and the third lands 33C has the liquid channel 60 through which a working liquid 2b passes. Alternatively, any one or some of the first lands 33A, the second lands 33B, and the third lands 33C do not need to have the liquid channel 60. The first lands 33A, the second lands 33B, and the third lands 33C each may extend in a straight line or may have a selected shape, such as a curved shape, including a circular arc and an S-shape, and a bent line shape, such as a V-shape and an L-shape. In the specification, the first lands 33A, the second lands 33B, and the third lands 33C are collectively simply referred to as lands 33.

The first lands 33A extend from the vaporization region SR side, and the second lands 33B or the third lands 33C are connected midway to each of the first lands 33A in the extension direction. The first lands 33A overlap the vaporization region SR at one end side in the extension direction (negative side in the X direction). The other end side of the first lands 33A in the extension direction (positive side in the X direction) is preferably present in the condensation region CR at a position away from the vaporization region SR outward in the plane direction and may, for example, terminate at a supporting portion 39 (described later). In this case, one or a plurality of the second lands 33B and/or one or a plurality of the third lands 33C are connected to each of the first lands 33A. In the present embodiment, the first lands 33A have a substantially S-shaped curved part in midway and extend in the X direction in a plan view as a whole. In the present embodiment, the plurality of (two) first lands 33A is provided, and these first lands 33A are disposed substantially parallel to each other. The other end of the first land 33A in the extension direction may be further connected to another one of the first lands 33A.

The second lands 33B extend from the vaporization region SR side and are connected to the first land 33A. In other words, the second lands 33B overlap the vaporization region SR at one end side in the extension direction (negative side in the X direction) and are connected to the first land 33A at the other end side in the extension direction (positive side in the X direction). In the present embodiment, the second lands 33B extend in a straight line shape in the X direction in a plan view. Alternatively, the second lands 33B may have a selected shape, such as a curved shape, including a circular arc and an S-shape, and a bent line shape, including a V-shape and an L-shape. In the present embodiment, a plurality of (three) second lands 33B is provided, and these second lands 33B are disposed parallel to each other.

The third lands 33C are located in a region other than the vaporization region SR and are connected to the first land 33A. In other words, the third lands 33C are connected to the first land 33A at one end side in the extension direction (negative side in the X direction). The other end side of the third lands 33C in the extension direction (positive side in the X direction) is preferably present in the condensation region CR at a position away from the vaporization region SR outward in the plane direction and may, for example, terminate at the supporting portion 39 (described later). In the present embodiment, the third lands 33C extend in a straight line shape in the X direction in a plan view. Alternatively, the third lands 33C may have a selected shape, such as a curved shape, including a circular arc and an S-shape, and a bent line shape, including a V-shape and an L-shape. In the present embodiment, the plurality of (three) third lands 33C is provided, and these third lands 33C are disposed parallel to each other.

The vapor channel 50 is mainly a channel through which vapor of a working fluid (referred to as working vapor 2a as needed) passes. The vapor channel 50 extends from the first main body surface 31a to the second main body surface 31b and extends through the wick sheet 30.

As shown in FIGS. 4 and 5, the vapor channel 50 according to the present embodiment has a plurality of vapor passages 51. The vapor passages 51 are formed inside the frame 32 and outside the lands 33, that is, between the frame 32 and the lands 33 and between any adjacent two of the lands 33. The planar shape of each vapor passage 51 may be not only a long-slender rectangular shape but also a selected shape, such as a curved shape, including a circular arc and an S-shape, and a bent line shape, including a V-shape and an L-shape. The vapor channel 50 is partitioned into the plurality of vapor passages 51 by the plurality of lands 33.

As shown in FIG. 3, the vapor passages 51 are formed so as to extend from the first main body surface 31a to the second main body surface 31b of the wick sheet 30. The vapor passages 51 are formed so as to extend through the wick sheet 30 from the first main body surface 31a to the second main body surface 31b of the wick sheet 30. The vapor passages 51 may be referred to as through-spaces.

The vapor passages 51 may be formed by etching from each of the first main body surface 31a and second main body surface 31b of the wick sheet 30 in the etching process (described later). In this case, as shown in FIG. 3, each of the vapor passages 51 has first wall surfaces 53a formed in a curved shape and second wall surfaces 54a formed in a curved shape. The first wall surface 53a is located adjacent to the first main body surface 31a and is curved in a shape recessed inward of the land 33 in the width direction (Y direction). The second wall surface 54a is located adjacent to the second main body surface 31b and is curved in a shape recessed inward of the land 33 in the width direction (Y direction). The first wall surface 53a and the second wall surface 54a meet at the protrusion 55 formed so as to project inward of the vapor passage 51. The protrusion 55 may be formed in an acute angle shape in a sectional view. A plane area of the vapor passage 51 is minimum at a position where the protrusion 55 is present. The width w2 (see FIG. 3) of the vapor passage 51 may be, for example, greater than or equal to 100 μm and less than or equal to 5000 μm. Here, the width w2 of the vapor passage 51 is a width at the narrowest part of the vapor passage 51 and, in this case, means a distance measured in a direction (width direction) orthogonal to the extension direction of the vapor passage 51 at a position where the protrusion 55 is present. The width w2 of the vapor passage 51 corresponds to a gap between the adjacent lands 33 in the width direction (Y direction).

The position of the protrusion 55 in the thickness direction (Z direction) of the wick sheet 30 is shifted toward the second main body surface 31b with respect to a center position between the first main body surface 31a and the second main body surface 31b. Where the distance between the protrusion 55 and the second main body surface 31b is t5 (see FIG. 3), the distance t5 may be greater than or equal to 5% of the thickness t4 (see FIG. 3) of the wick sheet 30 (described later), or greater than or equal to 10% of the thickness t4, or greater than or equal to 20% of the thickness t4. The distance t5 may be less than or equal to 50% of the thickness t4 of the wick sheet 30, may be less than or equal to 40% of the thickness t4, or may be less than or equal to 30% of the thickness t4. Not limited to these, the position of the protrusion 55 in the thickness direction (Z direction) of the wick sheet 30 may be the center position between the first main body surface 31a and the second main body surface 31b or may be a position shifted toward the first main body surface 31a with respect to the center position. When the vapor passage 51 extends through in the thickness direction (Z direction) of the wick sheet 30, the position of the protrusion 55 is selectable.

In the present embodiment, the sectional shape of the vapor passage 51 is defined by the protrusion 55 formed so as to project inward of the vapor passage 51; however, the configuration is not limited thereto. For example, the sectional shape of the vapor passage 51 may be a trapezoidal shape or a rectangular shape or may be a barrel shape.

The vapor channel 50 including the vapor passages 51 configured in this way is part of the above-described sealed space 3. As shown in FIG. 3, the vapor channel 50 according to the present embodiment is mainly defined by the lower sheet 10, the upper sheet 20, and the frame 32 and lands 33 of the above-described wick sheet 30. Each of the vapor passages 51 has a relatively large channel cross-sectional area such that the working vapor 2a passes.

As shown in FIGS. 4 and 5, the plurality of vapor passages 51 includes first vapor passages 51A, second vapor passages 51B, and third vapor passages 51C. The first vapor passages 51A, the second vapor passages 51B, and the third vapor passages 51C each are a channel through which the working vapor 2a passes and each are formed between the plurality of lands 33 or between the frame 32 and the lands 33. The first vapor passages 51A, the second vapor passages 51B, and the third vapor passages 51C each may extend in a straight line or may have a selected shape, such as a curved shape, including a circular arc and an S-shape, and a bent line shape, such as a V-shape and an L-shape. The basic configuration, such as the sectional shape, of each of the first vapor passages 51A, the second vapor passages 51B, and the third vapor passages 51C is the same as the configuration of the above-described vapor passage 51. In the specification, the first vapor passages 51A, the second vapor passages 51B, and the third vapor passages 51C are collectively simply referred to as vapor passages 51.

The first vapor passages 51A extend from the vaporization region SR side, and the ends of the first vapor passages 51A in the extension direction are not in contact with any of the lands 33. The first vapor passages 51A overlap the vaporization region SR at one end side in the extension direction (negative side in the X direction). The other end side of the first vapor passages 51A in the extension direction (positive side in the X direction) is preferably present in the condensation region CR at a position away from the vaporization region SR outward in the plane direction and may, for example, terminate at the supporting portion 39 (described later). In this case, the plurality of (three) first vapor passages 51A is provided and includes the vapor passage disposed along the first lands 33A and the vapor passages disposed along the frame 32 Of these, the first vapor passage 51A disposed along the first lands 33A is located between the two first lands 33A. The first vapor passage 51A has a part curved in substantially an S-shape in midway and extends in the X direction in a plan view as a whole. The two first vapor passages 51A disposed along the frame 32 each extend in a straight line shape in the X direction in a plan view.

The second vapor passages 51B extend from the vaporization region SR, and the ends of the second vapor passages 51B in the extension direction are in contact with the first land 33A. In other words, the second vapor passages 51B overlap the vaporization region SR at one end side in the extension direction (negative side in the X direction) and contact with the first land 33A at the other end in the extension direction (positive side in the X direction) to terminate. The first land 33A or the second land 33B is disposed on each side of the second vapor passage 51B in the width direction (Y direction). In the present embodiment, the second vapor passages 51B extend in a straight line shape in the X direction in a plan view. In the present embodiment, the plurality of (three) second vapor passages 51B is provided, and these second vapor passages 51B are disposed parallel to one another.

The third vapor passages 51C are located in a region other than the vaporization region SR, and the ends of the third vapor passages 51C in the extension direction are in contact with the first land 33A. In other words, the third vapor passages 51C are connected to the first land 33A at one end side in the extension direction (negative side in the X direction). The other end side of the third vapor passages 51C in the extension direction (positive side in the X direction) is preferably present in the condensation region CR at a position away from the vaporization region SR outward in the plane direction and may, for example, terminate at the supporting portion 39 (described later). The first land 33A or the third land 33C is disposed on each side of the third vapor passage 51C in the width direction (Y direction). In the present embodiment, the third vapor passages 51C extend in a straight line shape in the X direction in a plan view. In the present embodiment, the plurality of (three) third vapor passages 51C is provided, and these third vapor passages 51C are disposed parallel to one another.

As shown in FIGS. 4 and 5, the supporting portion 39 that supports the ends of the lands 33 in the longitudinal direction (X direction) on the frame 32 is provided in the vapor channel 50. The supporting portion 39 supports any adjacent two of the lands 33. The supporting portion 39 is provided on one side (positive side in the X direction) of the lands 33 in the longitudinal direction (X direction). The supporting portion 39 may be provided on each side of the lands 33 in the longitudinal direction (X direction). The supporting portion 39 is preferably formed so as not to impede flow of the working vapor 2a that diffuses in the vapor channel 50. In this case, the supporting portion 39 is disposed adjacent to the first main body surface 31a of the wick sheet 30, and a space that communicates with the vapor channel 50 is formed adjacent to the second main body surface 31b. In FIGS. 4 and 5, the supporting portion 39 is indicated in gray. The supporting portion 39 is thinned by half-etching from the second main body surface 31b side. The supporting portion 39 is a region that does not extend through the wick sheet 30 in the thickness direction and is less in thickness than the frame 32. As a result, the thickness of the supporting portion 39 can be made less than the thickness of the wick sheet 30, so it is possible to suppress separation of each of the vapor passages 51 in the X direction or in the Y direction. However, the configuration is not limited thereto. The supporting portion 39 may be disposed adjacent to the second main body surface 31b. A space that communicates with the vapor channel 50 may be formed on each of the first main body surface 31a-side surface and second main body surface 31b-side surface of the supporting portion 39.

As shown in FIG. 2, the vapor chamber 1 may further include a filling portion 4 at one-side (negative-side in the X direction) edge in the X direction. The filling portion 4 is used to fill the working liquid 2b into the sealed space 3. In the mode shown in FIG. 2, the filling portion 4 is disposed adjacent to the vaporization region SR. The filling portion 4 has a filling channel 37 formed in the wick sheet 30. The filling channel 37 is formed adjacent the second main body surface 31b of the wick sheet 30 and is formed into a recess shape from the second main body surface 31b side. After the vapor chamber 1 is complete, the filling channel 37 is sealed. The filling channel 37 communicates with the vapor channel 50, and the working liquid 2b is filled into the sealed space 3 through the filling channel 37. Depending on the arrangement of the liquid channels 60, the filling channel 37 may communicate with the liquid channels 60.

In the present embodiment, an example in which the filling portion 4 is provided at one-side edge of a pair of edges of the vapor chamber 1 in the X direction is described; however, the configuration is not limited thereto. The filling portion 4 may be provided at a selected position.

As shown in FIGS. 3, 4, and 6, the liquid channels 60 are provided on the second main body surface 31b of the wick sheet 30. The liquid channels 60 are mainly channels through which the working liquid 2b passes. The liquid channels 60 are part of the above-described sealed space 3 and communicate with the vapor channel 50. Each of the liquid channels 60 is configured as a capillary structure (wick) for transferring the working liquid 2b to the vaporization region SR. In the present embodiment, the liquid channel 60 is provided on the second main body surface 31b of each of the lands 33 of the wick sheet 30. The liquid channels 60 may be formed over the entire second main body surface 31b of each land 33. Of the plurality of lands 33, the liquid channel 60 does not need to be formed in one or some of the lands 33. The liquid channels 60 may also be referred to as second main body surface-side grooves.

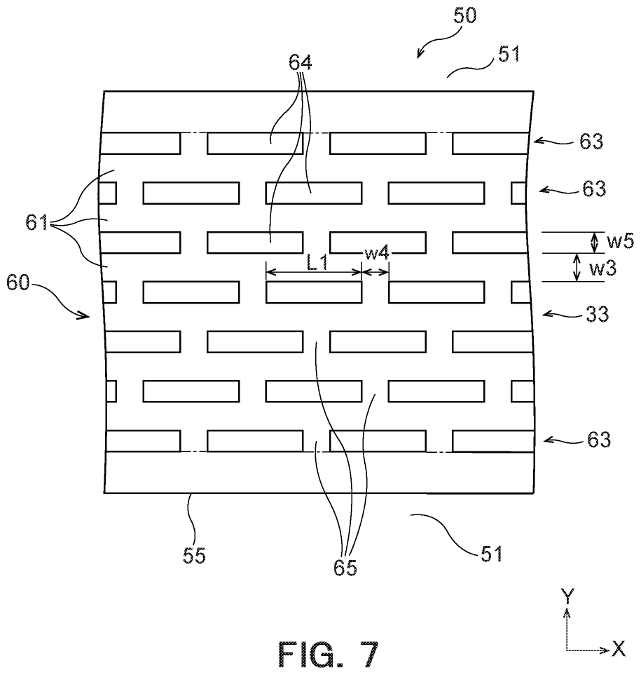

As shown in FIG. 7, the working liquid 2b passes through the liquid channel 60, and the liquid channel 60 has a plurality of liquid channel main stream grooves 61 disposed parallel to one another, and a plurality of liquid channel communication grooves 65 that communicate with the liquid channel main stream grooves 61. In the example shown in FIG. 7, each land 33 includes six liquid channel main stream grooves 61; however, the configuration is not limited thereto. The number of the liquid channel main stream grooves 61 included in each land 33 is selectable and may be, for example, greater than or equal to three and less than or equal to 20.

As shown in FIG. 7, each liquid channel main stream groove 61 is formed so as to extend in the extension direction (the longitudinal direction or the X direction) of the land 33. The plurality of liquid channel main stream grooves 61 is disposed parallel to one another. When the land 33 is curved in a plan view, each liquid channel main stream groove 61 may extend in a curved shape in a curved direction of the land 33. In other words, each liquid channel main stream groove 61 does not always need to be formed in a linear shape or does not need to extend parallel to the X direction.

The liquid channel main stream groove 61 has a channel cross-sectional area smaller than that of the vapor passage 51 of the vapor channel 50 such that the working liquid 2b mainly flows by capillary action. The liquid channel main stream grooves 61 are configured to transfer the working liquid 2b, produced by condensation of the working vapor 2a, to the vaporization region SR. The liquid channel main stream grooves 61 are disposed at intervals from each other in the width direction (a direction orthogonal to the extension direction of the land 33, or the Y direction).

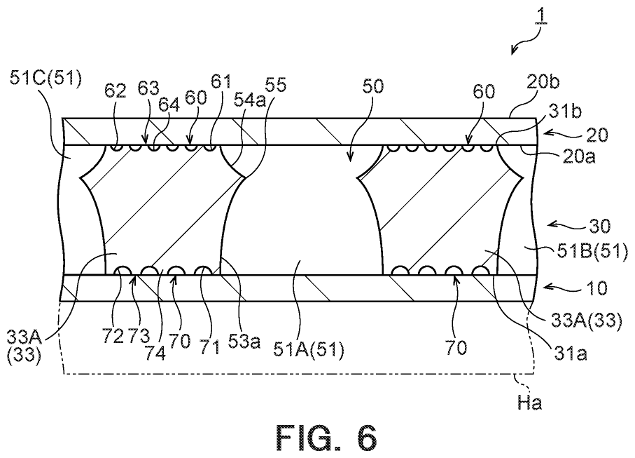

The liquid channel main stream grooves 61 are formed by etching from the second main body surface 31b of the wick sheet 30 in the etching process (described later). Each liquid channel main stream groove 61 has a wall surface 62 formed in a curved shape as shown in FIGS. 3 and 6. The wall surface 62 defines the liquid channel main stream groove 61 and is curved so as to be recessed from the second main body surface 31b side toward the first main body surface 31a side. In the cross section shown in FIGS. 3 and 6, the radius of curvature of each wall surface 62 is preferably less than the radius of curvature of the second wall surface 54a of the vapor passage 51.

In FIG. 7, the width w3 of the liquid channel main stream groove 61 may be, for example, greater than or equal to 2 μm and less than or equal to 500 μm. The width w3 of the liquid channel main stream groove 61 is the length in a direction orthogonal to the extension direction of the land 33 (a direction perpendicular to the longitudinal direction) and, in this case, a dimension in the Y direction. The width w3 of the liquid channel main stream groove 61 means a dimension at the second main body surface 31b. As shown in FIG. 3, the depth h1 of the liquid channel main stream groove 61 may be, for example, greater than or equal to 3 am and less than or equal to 300 μm. The depth h1 of the liquid channel main stream groove 61 is a distance measured in a direction perpendicular to the second main body surface 31b from the second main body surface 31b and, in this case, is a dimension in the Z direction. The depth h1 means a depth at the deepest point of the liquid channel main stream groove 61.

As shown in FIG. 7, each liquid channel communication groove 65 extends in a direction different from the extension direction (X direction) of the land 33. In the present embodiment, the liquid channel communication grooves 65 are formed so as to extend in the width direction (Y direction) of the land 33 and are formed perpendicularly to the liquid channel main stream grooves 61. Some of the liquid channel communication grooves 65 each are disposed so as to communicate adjacent two of the liquid channel main stream grooves 61. The other liquid channel communication grooves 65 each are disposed so as to communicate the vapor channel 50 (vapor passage 51) with the liquid channel main stream groove 61 closest to the vapor channel 50. In other words, the liquid channel communication groove 65 extends from an end side of the land 33 in the width direction to the liquid channel main stream groove 61 adjacent to the end. In this way, the vapor passage 51 of the vapor channel 50 communicates with the liquid channel main stream groove 61.

The liquid channel communication groove 65 has a channel cross-sectional area smaller than that of the vapor passage 51 of the vapor channel 50 such that the working liquid 2b mainly flows by capillary action. The liquid channel communication grooves 65 may be disposed so as to be spaced at equal intervals in the extension direction (the longitudinal direction or the X direction) of the land 33.

Each of the liquid channel communication grooves 65, as well as the liquid channel main stream grooves 61, is formed by etching and has a wall surface (not shown) formed in a curved shape similar to that of the liquid channel main stream groove 61. As shown in FIG. 7, the width w4 of the liquid channel communication groove 65 (a dimension in the extension direction of the land 33) may be greater than or equal to 5 μm and less than or equal to 300 μm. The depth of the liquid channel communication groove 65 may be greater than or equal to 3 am and less than or equal to 300 μm.

As shown in FIG. 7, a protrusion array 63 is provided between adjacent two of the liquid channel main stream grooves 61 of the liquid channel 60. In the example shown in FIG. 7, an example in which each land 33 includes seven protrusion arrays 63 is described; however, the configuration is not limited thereto. The number of the protrusion arrays 63 included in each land 33 is selectable and may be, for example, greater than or equal to three and less than or equal to 20.

As shown in FIG. 7, each protrusion array 63 is formed so as to extend in the extension direction (X direction) of the land 33. The plurality of protrusion arrays 63 is disposed parallel to one another. When the land 33 is curved in a plan view, each protrusion array 63 may extend in a curved shape in a curved direction of the land 33. In other words, each protrusion array 63 does not always need to be formed in a linear shape or does not need to extend parallel to the extension direction of the land 33. The protrusion arrays 63 are disposed so as to be spaced at intervals from each other in the width direction (Y direction) of the land 33.

Each protrusion array 63 includes a plurality of protrusions 64 (liquid channel protrusions) arranged in the extension direction of the land 33. The protrusions 64 are provided in the liquid channel 60. The protrusions 64 protrude from the liquid channel main stream grooves 61 and the liquid channel communication grooves 65 and contact with the upper sheet 20. Each of the protrusions 64 is formed in a rectangular shape in a plan view such that the extension direction of the land 33 is the longitudinal direction. The liquid channel main stream groove 61 is disposed between any adjacent two of the protrusions 64 in the width direction of the land 33. The liquid channel communication groove 65 is disposed between any adjacent two of the protrusions 64 in the extension direction of the land 33. The liquid channel communication groove 65 is formed so as to extend in the width direction of the land 33 and communicates adjacent two of the liquid channel main stream grooves 61 in the width direction of the land 33. As a result, the working liquid 2b is allowed to move among these liquid channel main stream grooves 61.

The protrusions 64 are portions where the material of the wick sheet 30 is left without being removed by etching in the etching process (described later). In the present embodiment, as shown in FIG. 7, the planar shape of each protrusion 64 (the shape at the position of the second main body surface 31b of the wick sheet 30) is a rectangular shape. The width w5 of the protrusion 64 may be, for example, greater than or equal to 5 μm and less than or equal to 500 μm.

In the present embodiment, the protrusions 64 are disposed in a staggered manner (alternately). More specifically, the protrusions 64 of the adjacent two of the protrusion arrays 63 in the width direction of the land 33 are disposed so as to be shifted from each other in the extension direction of the land 33. The shift amount may be half the array pitch of the protrusions 64 in the extension direction of the land 33. The arrangement of the protrusions 64 is not limited to the staggered manner and may be a parallel array. In this case, the protrusions 64 of adjacent two of the protrusion arrays 63 in the width direction of the land 33 are aligned also in the extension direction of the land 33.

The length L1 (a dimension in the extension direction of the land 33) of the protrusion 64 may be uniform among the protrusions 64. The length L1 of the protrusion 64 is greater than the width w4 of the liquid channel communication groove 65 (L1>w4). The length L1 of the protrusion 64 means a maximum dimension measured in the extension direction of the land 33 at the second main body surface 31b.

As shown in FIGS. 3, 5, and 6, the first main body surface-side channels 70 are provided on the first main body surface 31a of the wick sheet 30. The first main body surface-side channels 70 mainly play a role as liquid storage portions that store the working liquid 2b or play a role in passing the working vapor 2a by communicating with the vapor passages 51. The first main body surface-side channels 70 are part of the above-described sealed space 3. The first main body surface-side channels 70 communicate with the vapor passages 51 and also communicate with the liquid channels 60 via the vapor passages 51. In the present embodiment, the first main body surface-side channel 70 is provided on the first main body surface 31a side of each of the first lands 33A and the first main body surface 31a side of each of the second lands 33B. The first main body surface-side channel 70 does not need to be formed in one or some of the plurality of lands 33. The first main body surface-side channels 70 may also be referred to as first main body surface-side grooves.

As shown in FIG. 5, the first main body surface-side channels 70 may be disposed on the vaporization region SR side. The first main body surface-side channel 70 may be formed continuously or discontinuously to a predetermined position from the end of the land 33 in the extension direction on the vaporization region SR side toward the other end in the extension direction. The first main body surface-side channel 70 may be disposed in the vaporization region SR or part of the first main body surface-side channel 70 may extend outward of the vaporization region SR. When at least part of the first main body surface-side channel 70 is disposed in the vaporization region SR, the working liquid 2b stored in the first main body surface-side channel 70 easily vaporizes upon receiving heat of the device D.

In the present embodiment, the first main body surface-side channels 70 are also formed in connection regions MR that are regions in which the ends of the second vapor passages 51B or the third vapor passages 51C in the extension direction are in contact with the first land 33A. For example, in FIG. 5, the connection regions MR are respectively surrounded by circles and are present at positions where the ends of the second vapor passages 51B or the third vapor passages 51C in the extension direction are in contact with the first land 33A. At least in each of the connection regions MR, the first main body surface-side channel 70 is formed on the first main body surface 31a side of the first land 33A. The first main body surface-side channel 70 communicates with the second vapor passage 51B or the third vapor passage 51C, which is in contact with the first land 33A. Thus, the working vapor 2a from the second vapor passages 51B or the third vapor passages 51C passes through the first main body surface-side channel 70 and flows to the first vapor passages 51A across the first land 33A. The connection region MR may be located at a part where the first land 33A is curved in a plan view. In this case, in the connection region MR, it is possible to reduce the vapor resistance of the working vapor 2a flowing through the first main body surface-side channel 70, so it is possible to allow heat to be easily transferred in the plane of the vapor chamber 1.

As shown in FIG. 5, in the first land 33A located on the positive side in the Y direction, the first main body surface-side channel 70 is formed continuously from the connection regions MR to the vaporization region SR along the first land 33A. In the first land 33A located on the negative side in the Y direction, the first main body surface-side channel 70 is formed in each of the connection region MR and the vaporization region SR; however, the first main body surface-side channel 70 is not formed continuously from the connection regions MR to the vaporization region SR. In each second land 33B, the first main body surface-side channel 70 is formed continuously from the connection region MR to the vaporization region SR along the second land 33B. The first main body surface-side channel 70 is not formed in the third lands 33C. However, the configuration is not limited thereto. The first main body surface-side channel 70 may be formed in the third lands 33C.

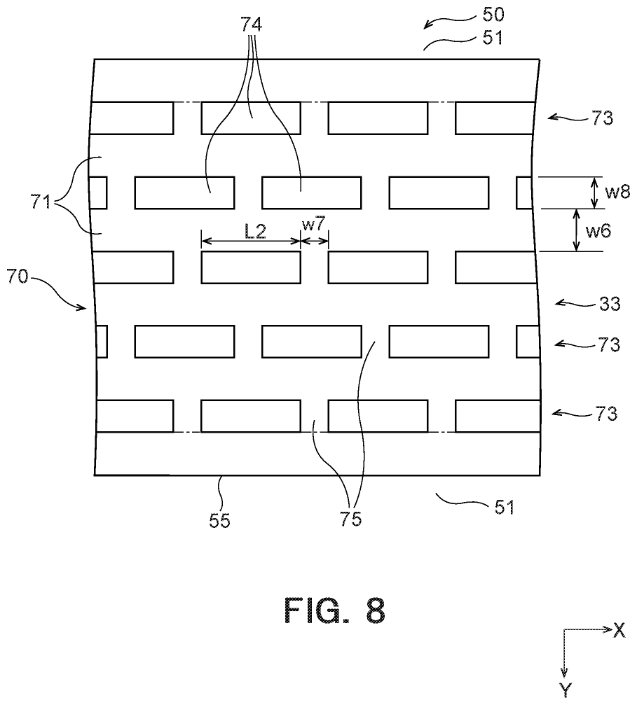

As shown in FIG. 8, the first main body surface-side channel 70 has a plurality of first main body surface-side main stream grooves 71 disposed parallel to one another, and a plurality of first main body surface-side communication grooves 75 that communicate with the first main body surface-side main stream grooves 71. The first main body surface-side main stream grooves 71 and the first main body surface-side communication grooves 75 are grooves through which the working liquid 2b or the working vapor 2a passes. In the example shown in FIG. 8, each land 33 includes five first main body surface-side main stream grooves 71; however, the configuration is not limited thereto. The number of the first main body surface-side main stream grooves 71 included in each land 33 is selectable and may be, for example, greater than or equal to two and less than or equal to 20.

As shown in FIG. 8, each first main body surface-side main stream groove 71 is formed so as to extend in the longitudinal direction (X direction) of the land 33. The plurality of first main body surface-side main stream grooves 71 is disposed parallel to one another. When the land 33 is curved in a plan view, each first main body surface-side main stream groove 71 may extend in a curved shape in a curved direction of the land 33. In other words, each first main body surface-side main stream groove 71 does not always need to be formed in a linear shape or does not need to extend parallel to the X direction.

Each first main body surface-side main stream groove 71 is formed in a predetermined range in the extension direction of the land 33. The first main body surface-side main stream groove 71 may have a channel cross-sectional area such that the working liquid 2b flows by capillary action. The channel cross-sectional area of the first main body surface-side main stream groove 71 is less than the channel cross-sectional area of the vapor passage 51. The channel cross-sectional area of the first main body surface-side main stream groove 71 may be greater than the channel cross-sectional area of the above-described liquid channel main stream groove 61. A capillary force that acts on the working liquid 2b in the first main body surface-side main stream groove 71 may be smaller than a capillary force that acts on the working liquid 2b in the liquid channel main stream groove 61. In this way, the first main body surface-side main stream groove 71 can introduce the working liquid 2b into the first main body surface-side channel 70 and can ensure the storage amount of the working liquid 2b. The first main body surface-side main stream grooves 71 may be disposed so as to be spaced at equal intervals in the width direction (Y direction).

The first main body surface-side main stream grooves 71 are formed by etching from the first main body surface 31a of the wick sheet 30 in the etching process (described later). As a result, each first main body surface-side main stream groove 71 has a wall surface 72 formed in a curved shape as shown in FIGS. 3 and 6. The wall surface 72 defines the first main body surface-side main stream groove 71 and is curved in a shape swelling toward the second main body surface 31b.

As shown in FIG. 8, the width w6 of the first main body surface-side main stream groove 71 may be greater than the width w3 of the above-described liquid channel main stream groove 61. The width w6 may be, for example, greater than or equal to 10 μm and less than or equal to 750 μm. The width w6 of the first main body surface-side main stream groove 71 means a dimension at the first main body surface 31a. The width w6 is the length in a direction perpendicular to the longitudinal direction of the land 33 and, in this case, a dimension in the Y direction. As shown in FIG. 6, the depth h2 of the first main body surface-side main stream groove 71 may be greater than the depth h1 of the above-described liquid channel main stream groove 61. The depth h2 may be, for example, greater than or equal to 5 am and less than or equal to 500 μm. The depth h2 corresponds to a dimension in the Z direction.

As shown in FIG. 8, the first main body surface-side communication grooves 75 extend in a direction different from the X direction. In the present embodiment, the first main body surface-side communication grooves 75 are formed so as to extend in the Y direction and are formed perpendicularly to the first main body surface-side main stream grooves 71. Some of the first main body surface-side communication grooves 75 each communicate adjacent two of the first main body surface-side main stream grooves 71. The other first main body surface-side communication grooves 75 communicate the vapor channel 50 (vapor passages 51) with the first main body surface-side main stream grooves 71. In other words, the first main body surface-side communication groove 75 extends from an end side of the land 33 in the Y direction to the first main body surface-side main stream groove 71 adjacent to the end. In this way, the vapor passages 51 of the vapor channel 50 communicate with the first main body surface-side main stream grooves 71.

The first main body surface-side communication groove 75 may have a channel cross-sectional area such that the working liquid 2b flows by capillary action. The channel cross-sectional area of the first main body surface-side communication groove 75 is less than the channel cross-sectional area of the vapor passage 51. The channel cross-sectional area of the first main body surface-side communication groove 75 may be greater than the channel cross-sectional area of the above-described liquid channel communication groove 65. A capillary force that acts on the working liquid 2b in the first main body surface-side communication groove 75 may be smaller than a capillary force that acts on the working liquid 2b in the liquid channel communication groove 65. In this way, the first main body surface-side communication groove 75 can introduce the working liquid 2b into the first main body surface-side channel 70 and can ensure the storage amount of the working liquid 2b. The first main body surface-side communication grooves 75 may be disposed so as to be spaced at equal intervals in the longitudinal direction (X direction) of the land 33.

Each of the first main body surface-side communication grooves 75, as well as the first main body surface-side main stream grooves 71, is formed by etching and has a wall surface (not shown) formed in a curved shape similar to that of the first main body surface-side main stream groove 71. The width w7 of the first main body surface-side communication groove 75 may be equal to the width w6 of the first main body surface-side main stream groove 71 or may be different from the width w6 of the first main body surface-side main stream groove 71 The width w7 corresponds to a dimension in the X direction. The depth of the first main body surface-side communication groove 75 may be equal to the depth h2 of the first main body surface-side main stream groove 71 or may be different from the depth h2 of the first main body surface-side main stream groove 71

As shown in FIG. 8, a protrusion array 73 is provided between adjacent two of the first main body surface-side main stream grooves 71. Each protrusion array 73 includes a plurality of protrusions 74 arranged in the longitudinal direction (X direction) of the land 33. The protrusions 74 are provided in the first main body surface-side channel 70. The protrusions 74 protrude from the first main body surface-side main stream grooves 71 and the first main body surface-side communication grooves 75 and contact with the lower sheet 10. Each protrusion 74 is formed in a rectangular shape such that the X direction is a longitudinal direction in a plan view. The first main body surface-side main stream groove 71 is interposed between adjacent two of the protrusions 74 in the Y direction. The first main body surface-side communication groove 75 is interposed between adjacent two of the protrusions 74 in the X direction. The first main body surface-side communication groove 75 extends in the width direction of the land 33 and communicates adjacent two of the first main body surface-side main stream grooves 71 in the width direction. As a result, the working liquid 2b or the working vapor 2a is allowed to move among these first main body surface-side main stream grooves 71.

The protrusions 74 are portions where the material of the wick sheet 30 is left without being etched in the etching process (described later). In the present embodiment, as shown in FIG. 8, the planar shape of the protrusion 74 is a rectangular shape. The planar shape of the protrusion 74 corresponds to a planar shape at the position of the first main body surface 31a.

In the present embodiment, the protrusions 74 are disposed in a staggered manner. More specifically, the protrusions 74 of adjacent two of the protrusion arrays 73 are disposed so as to be shifted from each other in the X direction. The shift amount may be half the array pitch of the protrusions 74 in the X direction. The width w8 of the protrusion 74 may be, for example, greater than or equal to 10 μm and less than or equal to 100 μm. The width w8 of the protrusion 74 means a dimension at the first main body surface 31a. The width w8 corresponds to a dimension in the width direction of the land 33. Arrangement of the protrusions 74 is not limited to a staggered manner and may be a parallel array. In this case, the protrusions 74 of adjacent two of the protrusion arrays 73 in the width direction of the land 33 are aligned also in the X direction. The width w6 of the first main body surface-side main stream groove 71 may be greater than w3 of the liquid channel main stream groove 61. The width w6 of the first main body surface-side main stream groove 71 may be less than the width w2 of the vapor passage 51.

The length L2 (a dimension in the X direction) of the protrusion 74 may be uniform among the protrusions 74. The length L2 of the protrusion 74 is greater than the width w7 of the first main body surface-side communication groove 75 (L2>w7). The length L2 of the protrusion 74 means a maximum dimension in the X direction at the first main body surface 31a.

The number of the first main body surface-side main stream grooves 71 provided in the land 33 may be less than the number of the liquid channel main stream grooves 61 provided in the land 33.

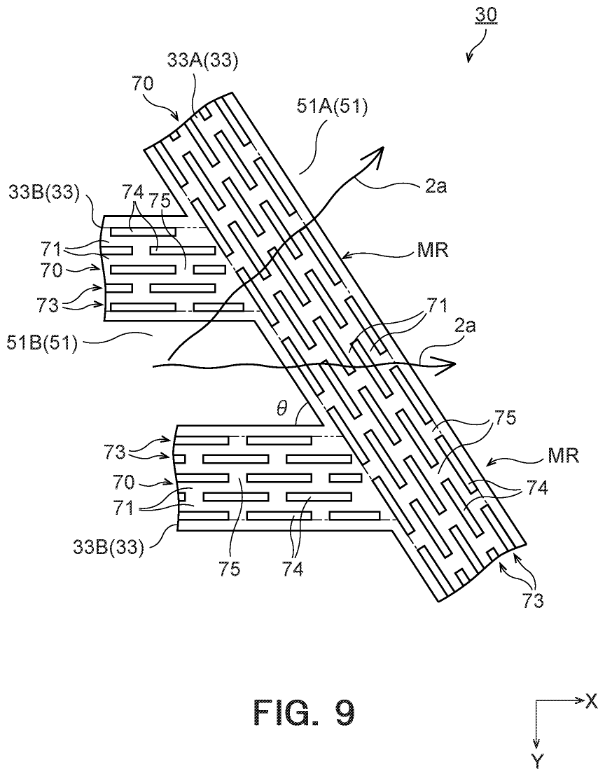

FIG. 9 is an enlarged bottom view (an enlarged view of portion VIII in FIG. 5) showing an area around the connection regions MR of the wick sheet 30. As shown in FIG. 9, the ends of the second vapor passages 51B in the extension direction (positive-side ends in the X direction) are in contact with the first land 33A, and the connection regions MR are formed in this region. The second land 33B is disposed on each side of the second vapor passage 51B in the width direction (Y direction). The second vapor passage 51B and the second lands 33B are located parallel to each other. The first vapor passage 51A that is a vapor passage different from the second vapor passage 51B is present on an opposite side of the connection region MR to a side where the end of the second vapor passage 51B in the extension direction (positive-side end in the X direction) is in contact with the first land 33A. In other words, the first vapor passage 51A is located on an opposite side of the first land 33A to the second vapor passage 51B. The first vapor passage 51A and the first land 33A are located parallel to each other.

At least in each connection region MR of the first land 33A, the first main body surface-side channel 70 that communicates with the second vapor passage 51B is formed. In this case, the first main body surface-side channel 70 is formed not only in the connection region MR but also in a region around the connection region MR, of the first land 33A. The first main body surface-side channel 70 is also continuously formed in the second land 33B connected to the first land 33A around the connection region MR. Furthermore, in the connection region MR, the first land 33A and the second vapor passage 51B intersect at an angle not a right angle in a plan view. In other words, the angle θ shown in FIG. 9 is an acute angle or an obtuse angle. Thus, it is possible to allow the working vapor 2a from the second vapor passage 51B to easily flow in the extension direction of the first land 33A, so it is possible to cause the working vapor 2a to go around in a wide region of the vapor chamber 1.

As shown in FIG. 9, the first main body surface-side channel 70 of the first land 33A has the plurality of protrusions 74 disposed in a staggered manner. The first main body surface-side main stream grooves 71 and the first main body surface-side communication grooves 75 are formed between the protrusions 74. Thus, the second vapor passage 51B and the first vapor passage 51A communicate with each other via the first main body surface-side channel 70 of the first land 33A. Therefore, the working vapor 2a from the second vapor passage 51B is allowed to pass through the first main body surface-side channel 70 of the first land 33A and flow toward the first vapor passage 51A.

Around the connection region MR, the first main body surface-side channel 70 may be formed in the second land 33B. Thus, the working vapor 2a from the second vapor passage 51B flows from the first main body surface-side channel 70 of the second land 33B toward the first vapor passage 51A via the first main body surface-side channel 70 of the first land 33A. Therefore, the working vapor 2a from the second vapor passage 51B is allowed to flow to the first vapor passage 51A adjacent to the first land 33A. The protrusions 74 of the first land 33A and the protrusions 74 of the second land 33B may be spaced apart from each other or the protrusions 74 of the first land 33A and the protrusions 74 of the second land 33B may be integrated with each other.

Incidentally, the material of the lower sheet 10, the upper sheet 20, and the wick sheet 30 is not limited as long as the material has a good thermal conductivity. The lower sheet 10, the upper sheet 20, and the wick sheet 30 may contain, for example, copper or a copper alloy. In this case, it is possible to enhance the thermal conductivity of each of the sheets 10, 20, 30, and it is possible to enhance the heat dissipation efficiency of the vapor chamber 1. When pure water is used as the working fluids 2a, 2b, it is possible to suppress corrosion. If it is possible to obtain a desired heat dissipation efficiency and suppress corrosion, another metal material, such as aluminum and titanium, or another metal alloy material, such as stainless steel, may be used for these sheets 10, 20, 30.

The thickness t1 of the vapor chamber 1 shown in FIG. 3 may be, for example, greater than or equal to 100 μm and less than or equal to 2000 μm. When the thickness t1 is greater than or equal to 100 μm, it is possible to cause the vapor chamber 1 to appropriately function by appropriately ensuring the vapor channel 50. On the other hand, when the thickness t1 is less than or equal to 2000 μm, it is possible to suppress an increase in the thickness t1 of the vapor chamber 1.

The thickness t2 of the lower sheet 10 may be, for example, greater than or equal to 5 μm and less than or equal to 500 μm. When the thickness t2 is greater than or equal to 5 μm, it is possible to ensure the mechanical strength of the lower sheet 10. On the other hand, when the thickness t2 is less than or equal to 500 μm, it is possible to suppress an increase in the thickness t1 of the vapor chamber 1. Similarly, the thickness t3 of the upper sheet 20 may be set as in the case of the thickness t2 of the lower sheet 10. The thickness t3 of the upper sheet 20 and the thickness t2 of the lower sheet 10 may be different from each other.

The thickness t4 of the wick sheet 30 may be, for example, greater than or equal to 50 μm and less than or equal to 1000 μm. When the thickness t4 is greater than or equal to 50 μm, it is possible to cause the vapor chamber 1 to appropriately function by appropriately ensuring the vapor channel 50. On the other hand, when the thickness t4 is less than or equal to 1000 μm, it is possible to suppress an increase in the thickness t1 of the vapor chamber 1.

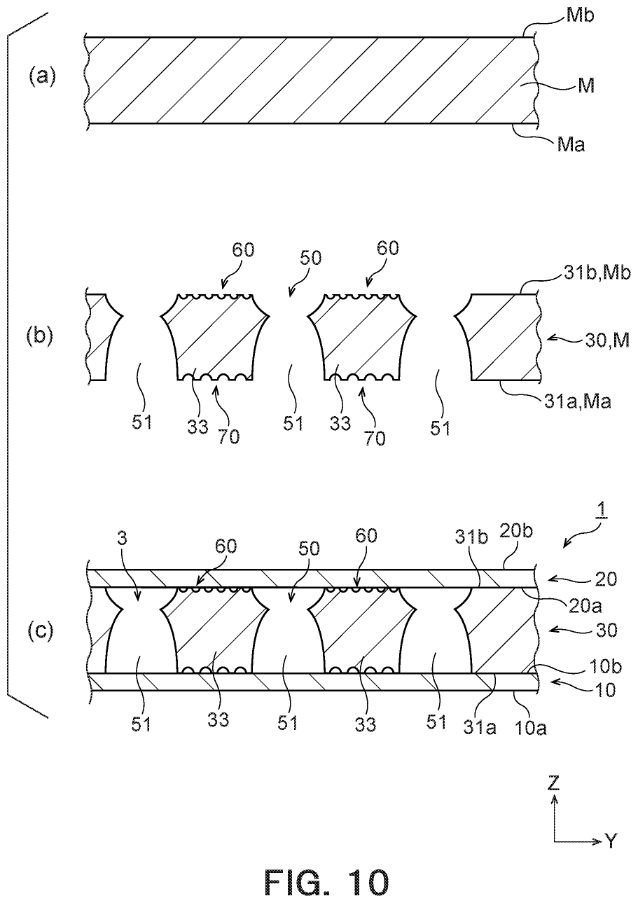

Next, a manufacturing method for the thus configured vapor chamber 1 according to the present embodiment will be described with reference to FIGS. 10(a) to 10(c). FIGS. 10(a) to 10(c) show substantially similar sectional views to the sectional view of FIG. 3.

Here, initially, a manufacturing process for the wick sheet 30 will be described.

Initially, as shown in FIG. 10(a), in a preparation process, a sheet-shaped metal material sheet M including a first material surface Ma and a second material surface Mb is prepared.

After the preparation process, as the etching process, as shown in FIG. 10(b), the metal material sheet M is etched from the first material surface Ma and the second material surface Mb to form the vapor channel 50, the liquid channels 60, and the first main body surface-side channels 70.

More specifically, a patterned resist film (not shown) is formed on the first material surface Ma and the second material surface Mb of the metal material sheet M by a photolithography technology. Subsequently, the first material surface Ma and second material surface Mb of the metal material sheet M are etched through the openings of the patterned resist film. Thus, the first material surface Ma and second material surface Mb of the metal material sheet M are etched into a patterned shape to form the vapor channel 50, the liquid channels 60, and the first main body surface-side channels 70 as shown in FIG. 10(b). For example, a ferric chloride etchant, such as aqueous ferric chloride, or a copper chloride etchant, such as aqueous copper chloride, may be used as an etchant.

The first material surface Ma and second material surface Mb of the metal material sheet M may be etched at the same time. However, not limited to this configuration, etching of the first material surface Ma and etching of the second material surface Mb may be performed in different processes. The vapor channel 50, the liquid channels 60, and the first main body surface-side channels 70 may be formed by etching at the same time or may be formed in different processes. In the etching process, a predetermined outline shape as shown in FIGS. 4 and 5 can be obtained by etching the first material surface Ma and second material surface Mb of the metal material sheet M. In other words, the end edge of the wick sheet 30 is formed.

In this way, the wick sheet 30 according to the present embodiment is obtained.

After the manufacturing process of the wick sheet 30, the lower sheet 10, the upper sheet 20, and the wick sheet 30 are joined together as shown in FIG. 10(c) in a joining process. The lower sheet 10 and the upper sheet 20 may be formed from a rolled material having a desired thickness.

More specifically, initially, the lower sheet 10, the wick sheet 30, and the upper sheet 20 are laminated in this order. In this case, the first main body surface 31a of the wick sheet 30 is superimposed on the second lower sheet surface 10b of the lower sheet 10, and the first upper sheet surface 20a of the upper sheet 20 is superimposed on the second main body surface 31b of the wick sheet 30.

Subsequently, the lower sheet 10, the wick sheet 30, and the upper sheet 20 are temporarily joined. For example, these sheets 10, 20, 30 may be temporarily joined by spot resistance welding, or these sheets 10, 20, 30 may be temporarily joined by laser welding.

After that, the lower sheet 10, the wick sheet 30, and the upper sheet 20 are permanently joined by diffusion joining. Diffusion joining is a joining method as follows. In other words, initially, the lower sheet 10 and the wick sheet 30 to be joined are brought into close contact with each other, and the wick sheet 30 and the upper sheet 20 are brought into close contact with each other. Subsequently, the lower sheet 10, the wick sheet 30, and the upper sheet 20 are joined by means of diffusion of atoms that occurs on a joint surface by pressurizing and heating in a laminated direction in a controlled atmosphere, such as vacuum and inert gas. Diffusion joining heats the materials of the sheets 10, 20, 30 to a temperature close to a melting point but lower than the melting point, so it is possible to avoid melting and deformation of each of the sheets 10, 20, 30. More specifically, the first main body surface 31a at each of the frame 32 and the lands 33 of the wick sheet 30 is diffusion-joined with the second lower sheet surface 10b of the lower sheet 10. The second main body surface 31b at each of the frame 32 and the lands 33 of the wick sheet 30 is diffusion-joined with the first upper sheet surface 20a of the upper sheet 20 surface. In this way, the sheets 10, 20, 30 are diffusion-joined, and the sealed space 3 having the vapor channel 50, the liquid channels 60, and the first main body surface-side channels 70 is formed between the lower sheet 10 and the upper sheet 20.

After the joining process, the working liquid 2b is filled into the sealed space 3 through the filling portion 4.

After that, the above-described filling channel 37 is sealed. For example, the filling channel 37 may be sealed by partially melting the filling portion 4. Thus, communication between the sealed space 3 and the outside is interrupted, and the working liquid 2b is filled into the sealed space 3, so leakage of the working liquid 2b in the sealed space 3 to the outside is suppressed.

In this way, the vapor chamber 1 according to the present embodiment is obtained.

Next, an operation method for the vapor chamber 1, that is, a method of cooling the device D, will be described.

The vapor chamber 1 obtained as described above is installed in the housing H of the electronic apparatus E, such as a mobile terminal. The device D, such as a CPU, that is, a device to be cooled, is attached to the second upper sheet surface 20b of the upper sheet 20 (or the vapor chamber 1 is attached to the device D). The working liquid 2b in the sealed space 3 adheres, with its surface tension, to the wall surface of the sealed space 3, that is, the first wall surfaces 53a and second wall surfaces 54a of the vapor passages 51, and the wall surfaces 62 of the liquid channel main stream grooves 61 and the wall surfaces of the liquid channel communication grooves 65 of the liquid channels 60. The working liquid 2b can also adhere to portions exposed to the vapor passages 51, of the second lower sheet surface 10b of the lower sheet 10. Furthermore, the working liquid 2b can also adhere to portions exposed to the vapor passages 51, the liquid channel main stream grooves 61, and the liquid channel communication grooves 65, of the first upper sheet surface 20a of the upper sheet 20.

When the device D generates heat in this state, the working liquid 2b present in the vaporization region SR (see FIGS. 4 and 5) receives heat from the device D. The working liquid 2b absorbs the received heat as latent heat to be vaporized (evaporated) into the working vapor 2a. Most of the generated working vapor 2a diffuses in the vapor passages 51 that are components of the sealed space 3 (see the continuous line arrows in FIG. 4). The working vapor 2a in each vapor passage 51 leaves from the vaporization region SR, and most of the working vapor 2a is transferred to the condensation region CR with a relatively low temperature (a right-side part in FIGS. 4 and 5). In the condensation region CR, the working vapor 2a mainly dissipates heat to the lower sheet 10 to be cooled. Heat that the lower sheet 10 has received from the working vapor 2a is transferred to outside air via the housing member Ha (see FIG. 3).

In the present embodiment, of the plurality of vapor passages 51, the first vapor passages 51A directly extend from the vaporization region SR to the condensation region CR. Therefore, the working vapor 2a that passes through the first vapor passages 51A directly reaches the condensation region CR. On the other hand, the second vapor passages 51B extend from the vaporization region SR, and the ends of the second vapor passages 51B in the extension direction are in contact with the first land 33A. Therefore, the working vapor 2a that passes through the second vapor passages 51B is blocked by the first land 33A and is not directly transferred to the condensation region CR. In the present embodiment, the first main body surface-side channel 70 that communicates with the second vapor passages 51B is formed on the first main body surface 31a side of the first land 33A in the connection regions MR in which the ends of the second vapor passages 51B in the extension direction are in contact with the first land 33A. Thus, the working vapor 2a from the second vapor passages 51B crosses the first land 33A via the first main body surface-side channel 70 and flows to the first vapor passage 51A located on an opposite side to the second vapor passages 51B. After that, the working vapor 2a passes through the first vapor passage 51A and reaches the condensation region CR. Alternatively, part of the working vapor 2a crosses the first main body surface-side channel 70 formed in the other first land 33A and flows to the third vapor passages 51C. After that, the working vapor 2a passes through the third vapor passages 51C and reaches the condensation region CR.

The working vapor 2a dissipates heat to the lower sheet 10 in the condensation region CR and loses the absorbed latent heat in the vaporization region SR to be condensed into the working liquid 2b. The produced working liquid 2b adheres to the first wall surfaces 53a and second wall surfaces 54a of the vapor passages 51, the second lower sheet surface 10b of the lower sheet 10, and the first upper sheet surface 20a of the upper sheet 20. Here, the working liquid 2b continues to vaporize in the vaporization region SR. Therefore, the working liquid 2b in a region other than the vaporization region SR of the liquid channels 60 (that is, the condensation region CR) is transferred toward the vaporization region SR by the capillary action of the liquid channel main stream grooves 61 (see the dashed line arrows in FIG. 4). Thus, the working liquid 2b having adhered to the vapor passages 51, the second lower sheet surface 10b, and the first upper sheet surface 20a moves to the liquid channels 60, passes through the liquid channel communication grooves 65, and enters the liquid channel main stream grooves 61. In this way, the liquid channel main stream grooves 61 and the liquid channel communication grooves 65 are filled with the working liquid 2b. Therefore, the filled working liquid 2b gains propelling force toward the vaporization region SR by the capillary action of the liquid channel main stream grooves 61, and is transferred smoothly toward the vaporization region SR.

In the liquid channels 60, each liquid channel main stream groove 61 communicates with another adjacent one of the liquid channel main stream grooves 61 via corresponding some of the liquid channel communication grooves 65. Thus, the working liquid 2b moves between adjacent two of the liquid channel main stream grooves 61, so occurrence of dryout in the liquid channel main stream grooves 61 is suppressed. Therefore, the capillary action is imparted to the working liquid 2b in each liquid channel main stream groove 61, and the working liquid 2b is smoothly transferred toward the vaporization region SR.

The working liquid 2b having reached the vaporization region SR receives heat again from the device D to vaporize. The working vapor 2a vaporized from the working liquid 2b moves to the vapor passages 51 with a greater channel cross-sectional area through the liquid channel communication grooves 65 in the vaporization region SR and diffuses in the vapor passages 51. In this way, the working fluids 2a, 2b circulate in the sealed space 3 while repeating a phase change, that is, vaporization and condensation, to transfer and dissipate heat of the device D. As a result, the device D is cooled.

Part of the working liquid 2b condensed in the condensation region CR is not only transferred to the liquid channels 60 but also transferred to the first main body surface-side channels 70 to fill the first main body surface-side channels 70. As described above, part of the first main body surface-side channels 70 is disposed in the vaporization region SR. Therefore, the working liquid 2b filled in the first main body surface-side channels 70 gains propelling force by the capillary action of the first main body surface-side channels 70 and moves toward the vaporization region SR. The working liquid 2b having reached the vaporization region SR by the first main body surface-side channels 70 receives heat from the device D again to vaporize and diffuses in the vapor passages 51 again.

While the device D stops heat generation, the working liquid 2b in the vaporization region SR fills the liquid channels 60 to stay without vaporization. Therefore, the working liquid 2b in the condensation region CR stays without being transferred toward the vaporization region SR. Part of the working liquid 2b in the liquid channels 60 flows through the vapor passages 51 and moves into the first main body surface-side channels 70. Thus, the working liquid 2b fills the first main body surface-side channels 70 and stays. When the amount of the working liquid 2b filled in the sealed space 3 is larger than the total volume of space in the liquid channels 60, part of the working liquid 2b easily fills the insides of the first main body surface-side channels 70. Therefore, the working liquid 2b can be distributed to not only the liquid channels 60 but also the first main body surface-side channels 70 and stay.

In this state, even when the electronic apparatus E equipped with the vapor chamber 1 is put in a temperature environment lower than a freezing point of the working fluids 2a, 2b and, as a result, the working liquid 2b in the liquid channel 60 freezes to expand, the expansion force of the working fluids 2a, 2b is reduced. Thus, a deformation of the upper sheet 20 upon receiving a force due to expansion is suppressed. Therefore, it is possible to suppress a decrease in the flatness of the second upper sheet surface 20b of the upper sheet 20 to which the device D is attached, so it is possible to suppress formation of a gap between the second upper sheet surface 20b and the device D. In this case, it is possible to suppress interference with heat conduction from the device D, so it is possible to suppress a decrease in the performance of the vapor chamber 1. Similarly, even when the working liquid 2b in the first main body surface-side channels 70 freezes to expand, the expansion force is reduced. Thus, a deformation of the lower sheet 10 upon receiving a force due to expansion is suppressed. Therefore, it is possible to suppress a decrease in the flatness of the first lower sheet surface 10a of the lower sheet 10.

In this way, according to the present embodiment, the ends of the second vapor passages 51B in the extension direction are in contact with at least the first land 33A of the plurality of lands 33. The first main body surface-side channel 70 that communicates with the second vapor passages 51B is formed on the first main body surface 31a side of the first land 33A in the connection regions MR in which the ends of the second vapor passages 51B in the extension direction are in contact with the first land 33A. Thus, the working vapor 2a transferred from the vaporization region SR side via the second vapor passages 51B is allowed to be sent to the other first vapor passage 51A via the first main body surface-side channel 70. Therefore, it is possible to transfer the working vapor 2a in a direction away from the vaporization region SR, so it is possible to reduce a region to which heat is difficult to be transferred in the plane of the vapor chamber 1. Since a wide range of the vapor chamber 1 can be used to transfer heat, it is possible to cause heat from the heat source to go around uniformly in the plane of the vapor chamber 1. As a result, the action that the working fluids 2a, 2b circulate in the sealed space 3 is facilitated, so it is possible to improve the temperature holding ability of the vapor chamber 1.

According to the present embodiment, the first main body surface-side channel 70 is formed continuously to the vaporization region SR along the first land 33A. Thus, the first main body surface-side channel 70 can be used as a liquid channel that transfers the working liquid 2b to the vaporization region SR. As a result, it is possible to facilitate the action that the working fluids 2a, 2b circulate in the sealed space 3.

According to the present embodiment, the first main body surface-side channels 70 are also formed in the second lands 33B that extend along the second vapor passages 51B. In this case, the working vapor 2a transferred from the vaporization region SR side via the second vapor passages 51B is allowed to be sent to the first main body surface-side channel 70 of the first land 33A via the first main body surface-side channels 70 of the second lands 33B. Thus, since a wide range of the vapor chamber 1 can be used to transfer heat, it is possible to cause heat from the heat source to go around uniformly in the plane of the vapor chamber 1.

### (Modifications)

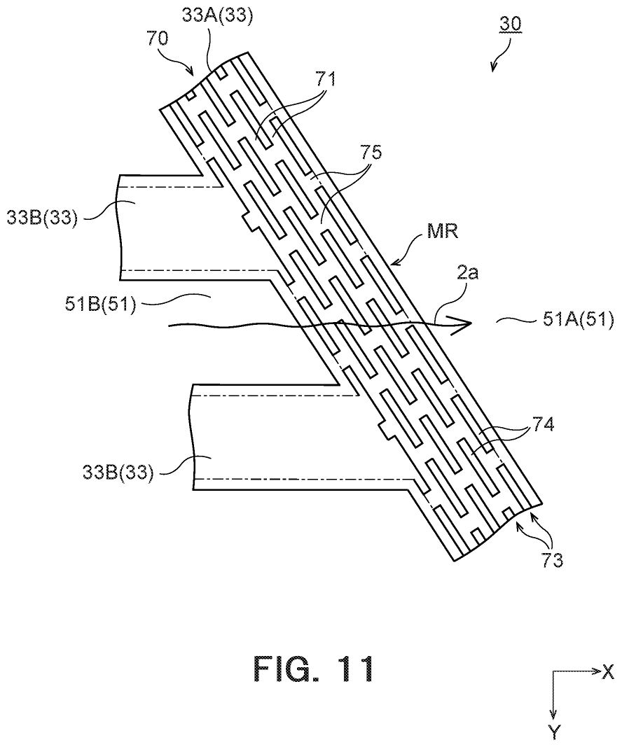

Next, various modifications of the first embodiment will be described with reference to FIGS. 11 to 18. FIGS. 11 to 18 are enlarged bottom views respectively showing parts of the wick sheet 30 according to the modifications. In FIGS. 11 to 18, like reference signs are assigned to the same portions as those of the embodiment shown in FIGS. 1 to 10, and the detailed description is omitted.

### (First Modification)

As shown in FIG. 11, the first main body surface-side channel 70 does not need to be formed in each of the second lands 33B located on both sides of the second vapor passage 51B in the width direction. The first main body surface-side channel 70 does not need to be formed over the entire region of the second land 33B. Alternatively, the first main body surface-side channel 70 may be formed in the vaporization region SR side of the second land 33B and does not need to be formed in the connection region MR side of the second land 33B. In this case, the working vapor 2a from the second vapor passage 51B is allowed to intensively flow in the extension direction (toward the positive side in the X direction) of the second vapor passage 51B and a larger amount of working vapor 2a can be transferred in the extension direction (toward the positive side in the X direction) of the second vapor passage 51B.

### (Second Modification)

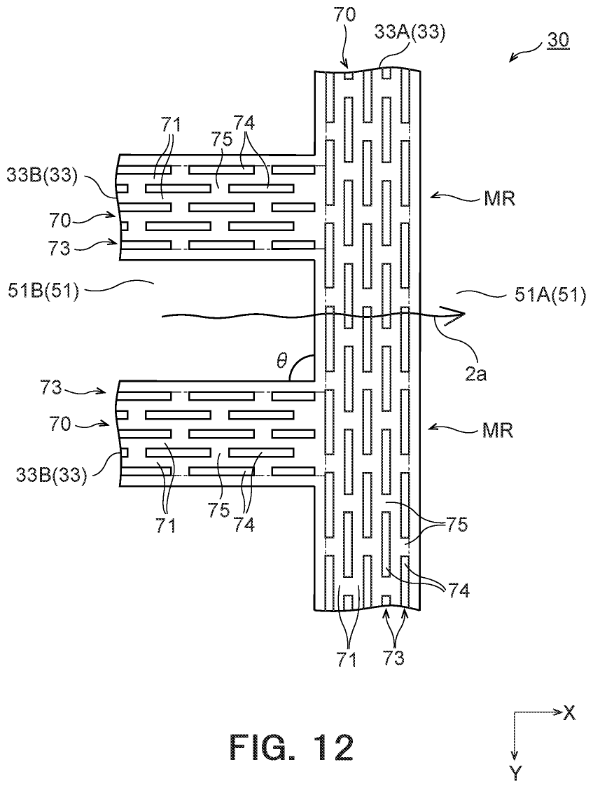

As shown in FIG. 12, in each of the connection regions MR of the first land 33A, the first land 33A and the second vapor passage 51B may be orthogonal to each other in a plan view. In other words, the angle θ in FIG. 12 may be 90°. In this case, the working vapor 2a from the second vapor passage 51B crosses the first land 33A perpendicularly to the extension direction of the first land 33A, so the working vapor 2a passes through the first land 33A by a minimum distance. Thus, it is possible to minimize the vapor resistance of the working vapor 2a that crosses the first land 33A.

### (Third Modification)

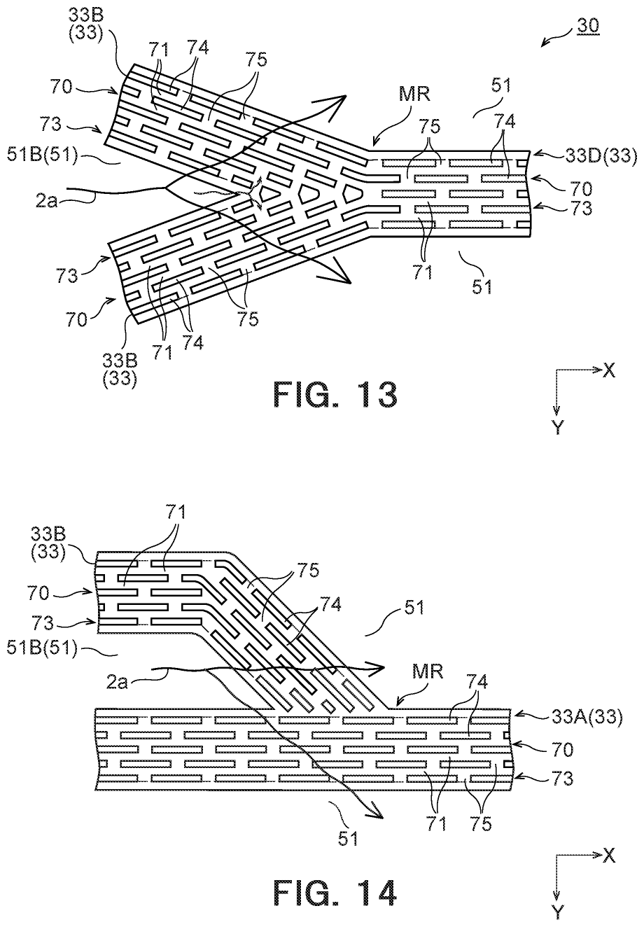

As shown in FIG. 13, the two second lands 33B may merge and connect with a fourth land 33D. At the merged part, the end of the second vapor passage 51B in the extension direction is in contact with the fourth land 33D. The first main body surface-side channels 70 that communicate with the second vapor passage 51B are formed on the first main body surface 31a side of the fourth land 33D in the connection region MR in which the end of the second vapor passage 51B in the extension direction is in contact with the fourth land 33D. One end in the extension direction (a negative-side end in the X direction) of the fourth land 33D may be connected to the two second lands 33B, and the other end in the extension direction (a positive-side end in the X direction) may be present in the condensation region CR away from the vaporization region SR outward in the plane direction. In this case, the second vapor passage 51B has a shape such that the width (distance in the Y direction) gradually narrows toward the connection region MR located at the end of the second vapor passage 51B in the extension direction.

According to the present modification, the working vapor 2a from the second vapor passage 51B can be bifurcated near the connection region MR and be caused to flow toward the vapor passages 51 located on both sides of the fourth land 33D in the width direction (Y direction). Thus, it is possible to cause the working vapor 2a to go around a wide region of the vapor chamber 1. The three or more second lands 33B may merge and connect with the fourth land 33D.

### (Fourth Modification)

As shown in FIG. 14, within the second land 33B, a part located adjacent to the connection region MR may be curved or bent to be connected to the first land 33A. In this case, the end of the second vapor passage 51B in the extension direction is in contact with the first land 33A. The first main body surface-side channel 70 that communicates with the second vapor passage 51B is formed on the first main body surface 31a side of the first land 33A in the connection region MR in which the end of the second vapor passage 51B in the extension direction in contact with the first land 33A. The second vapor passage 51B has a shape such that the width (distance in the Y direction) gradually narrows toward the connection region MR located at the end of the second vapor passage 51B in the extension direction.

According to the present modification, the working vapor 2a from the second vapor passage 51B can be bifurcated near the connection region MR and be caused to flow toward the vapor passages 51 located on both sides of the first land 33A in the width direction (Y direction). Thus, it is possible to cause the working vapor 2a to go around a wide region of the vapor chamber 1.

### (Fifth Modification)

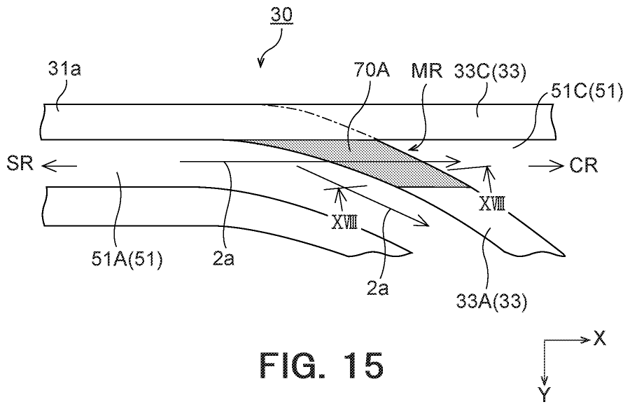

FIGS. 15 to 18 are views showing a fifth modification. Of these, FIGS. 15 to 17 are enlarged bottom views showing an area around the connection region MR of the wick sheet 30 according to the present modification.

As shown in FIGS. 15 to 17, a first main body surface-side channel 70A is formed on the first main body surface 31a side of the first land 33A in the connection region MR in which the end of the third vapor passage 51C in the extension direction is in contact with the first land 33A. The first main body surface-side channel 70A communicates with the first vapor passage 51A and the third vapor passage 51C. The connection region MR is thinned from the first main body surface 31a side. In this case, within the first land 33A, at least the thickness of a part where the first main body surface-side channel 70A is formed is less than the overall thickness of the wick sheet 30.

In FIGS. 15 to 17, in the lands 33A, 33C, a part thinned from the first main body surface 31a side and where the first main body surface-side channel 70A is formed is indicated in gray. In FIGS. 15 to 17, in the lands 33A, 33C, a part that is not thinned from the first main body surface 31a side or where the first main body surface-side channel 70 or the first main body surface-side channel 70A is not formed is indicated in white.

As shown in FIG. 15, the first main body surface-side channel 70A that communicates with the first vapor passage 51A and the third vapor passage 51C is formed in the connection region MR in which the end of the third vapor passage 51C in the extension direction is in contact with the first land 33A. In the first land 33A, a part adjacent to the connection region MR is not thinned from the first main body surface 31a side or the first main body surface-side channel 70 or the first main body surface-side channel 70A is not formed at the part.

In this case, during a stop of the vapor chamber 1, the working liquid 2b can be stored in the first main body surface-side channel 70A. During operation of the vapor chamber 1, the working vapor 2a is allowed to pass through the first main body surface-side channel 70A and easily flow into the third vapor passage 51C.

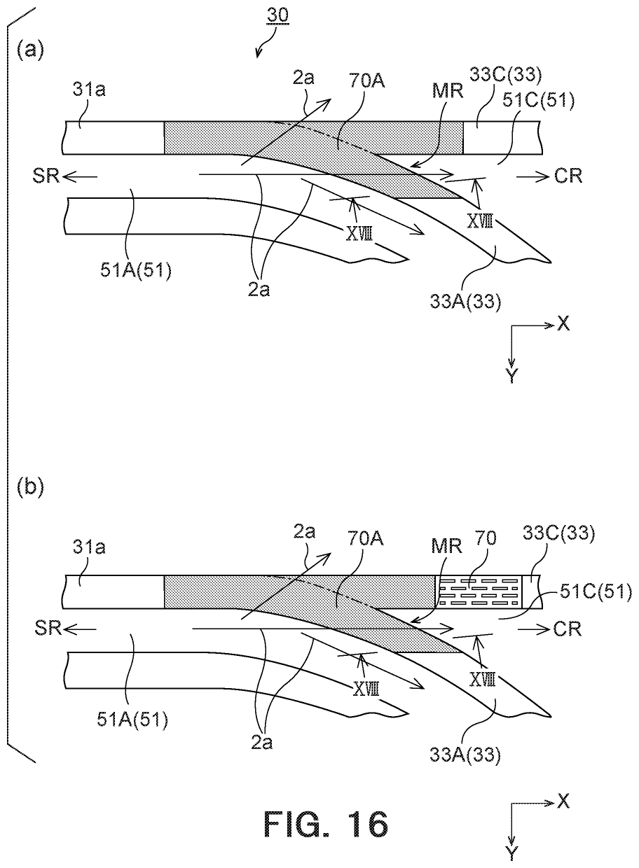

As shown in FIG. 16(a), the first main body surface-side channel 70A that communicates with the first vapor passage 51A and the third vapor passage 51C is formed in the connection region MR in which the end of the third vapor passage 51C in the extension direction is in contact with the first land 33A. The first main body surface-side channel 70A is formed at a connecting portion of the first land 33A with the third land 33C and a connecting portion of the third land 33C with the first land 33A.

In this case, during a stop of the vapor chamber 1, a larger amount of the working liquid 2b can be stored in the first main body surface-side channel 70A. During operation of the vapor chamber 1, a region in which the working vapor 2a can pass through can be widened. Furthermore, it is possible to control the direction in which the working vapor 2a flows.

As shown in FIG. 16(b), the first main body surface-side channel 70A that communicates with the first vapor passage 51A and the third vapor passage 51C is formed in the connection region MR in which the end of the third vapor passage 51C in the extension direction is in contact with the first land 33A. The first main body surface-side channel 70A is formed at a connecting portion of the first land 33A with the third land 33C and a connecting portion of the third land 33C with the first land 33A. Furthermore, the first main body surface-side channel 70 not thinned from the first main body surface 31a side is formed at a position adjacent to the first main body surface-side channel 70A in the third land 33C.

In this case, particularly, it is preferable to dispose the first main body surface-side channel 70 of the third land 33C at a position close to the condensation region CR. Thus, it is possible for the first main body surface-side channel 70 to draw up the working liquid 2b present in the third vapor passage 51C and easily flow the working liquid 2b to the adjacent first main body surface-side channel 70A.

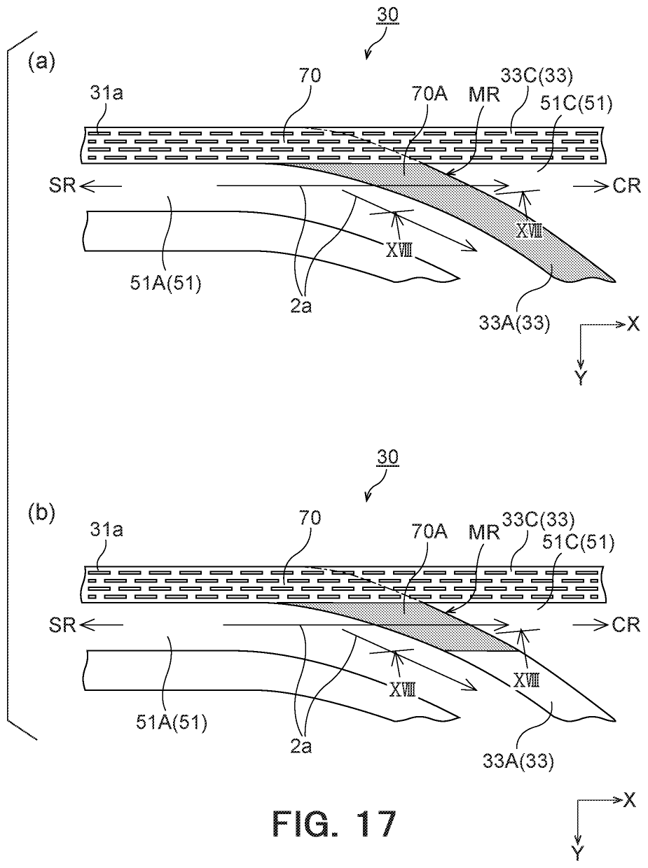

As shown in FIG. 17(a), the first main body surface-side channel 70A that communicates with the first vapor passage 51A and the third vapor passage 51C is formed in the connection region MR in which the end of the third vapor passage 51C in the extension direction is in contact with the first land 33A. The first main body surface-side channel 70A is also formed at a part far from the vaporization region SR beyond the connection region MR in the first land 33A. Furthermore, the first main body surface-side channel 70 that is not thinned from the first main body surface 31a side is formed at a part closer to the vaporization region SR than the connection region MR in the first land 33A. The first main body surface-side channel 70 of the first land 33A continuously extends to the vaporization region SR. Furthermore, the first main body surface-side channel 70 is also formed in the third land 33C.

In this case, the first main body surface-side channel 70 of the first land 33A can be used as a liquid channel that transfers the working liquid 2b to the vaporization region SR. The working liquid 2b stored in the first main body surface-side channel 70A is easily transferred to the vaporization region SR by using the first main body surface-side channel 70.

As shown in FIG. 17(b), the first main body surface-side channel 70A that communicates with the first vapor passage 51A and the third vapor passage 51C is formed in the connection region MR in which the end of the third vapor passage 51C in the extension direction is in contact with the first land 33A. A part farther from the vaporization region SR than the connection region MR in the first land 33A is not thinned from the first main body surface 31a side, and the first main body surface-side channel 70 or the first main body surface-side channel 70A is not formed at the part. The first main body surface-side channel 70 that is not thinned from the first main body surface 31a side is formed at a part closer to the vaporization region SR than the connection region MR in the first land 33A. The first main body surface-side channel 70 of the first land 33A continuously extends to the vaporization region SR. Furthermore, the first main body surface-side channel 70 is also formed in the third land 33C.

In this case, since a part adjacent to the connection region MR in the first land 33A is not thinned from the first main body surface 31a side, it is possible to suppress a deformation of the connection region MR in the thickness direction.

Although not shown in FIGS. 15 to 17, the first main body surface-side channel 70A may be formed in the connection region MR in which the end of the second vapor passage 51B in the extension direction is in contact with the first land 33A.

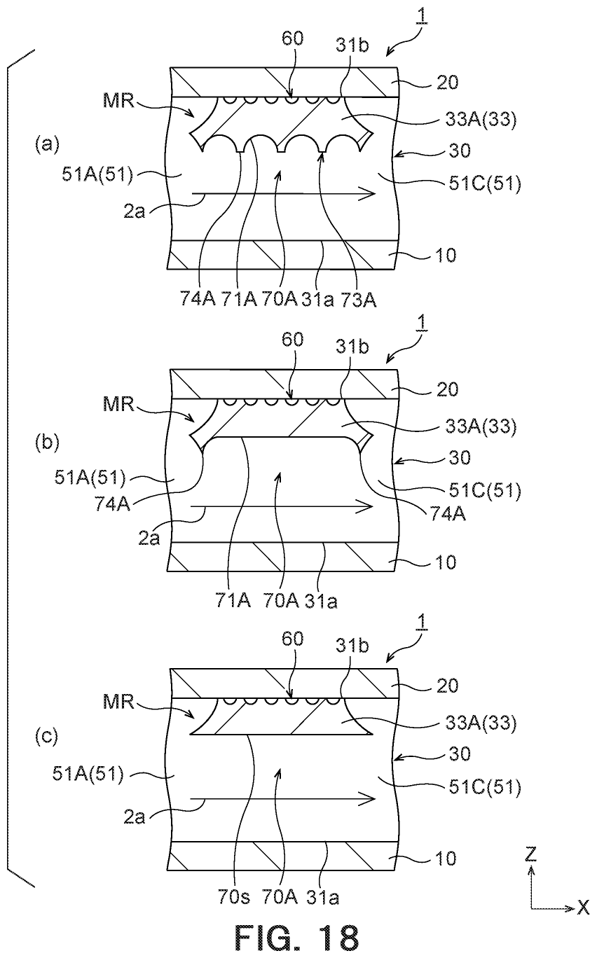

FIGS. 18(a) to 18(c) are sectional views (sectional views taken along the line XVIII-XVIII in FIGS. 15 to 17) in the connection region MR of the first land 33A. The connection region MR of the first land 33A shown in FIGS. 15 to 17 may have any of the sectional shapes of FIGS. 18(a) to 18(c).

As shown in FIG. 18(a), the first main body surface-side channel 70A may have a plurality of first main body surface-side main stream grooves 71A and a plurality of protrusion arrays 73A. The plurality of first main body surface-side main stream grooves 71A is disposed parallel to one another. Each protrusion array 73A is provided between adjacent two of the first main body surface-side main stream grooves 71A. Each protrusion array 73A includes a plurality of protrusions 74A arranged in the longitudinal direction of the first land 33A. The protrusions 74A are located adjacent to the second main body surface 31B with respect to the first main body surface 31a and are spaced apart from the lower sheet 10. The protrusions 74A may be disposed in a staggered manner in a plan view. Alternatively, each protrusion array 73A may include one protrusion 74A and the protrusion 74A may extend linearly in the longitudinal direction of the first land 33A.

In this case, the protrusions 74A of the first main body surface-side channel 70A are apart from the first main body surface 31a, so the space between the first land 33A and the lower sheet 10 expands. Thus, it is possible to store a larger amount of working liquid 2b in the first main body surface-side channel 70A. Furthermore, during operation of the vapor chamber 1, it is possible to cause the working vapor 2a to go around in a wide region of the vapor chamber 1.

In FIG. 18(a), the first main body surface-side main stream grooves 71A and the protrusion arrays 73A may extend in the flow direction (the arrow direction in FIG. 18(a)) of the working vapor 2a. In this case, flow of the working vapor 2a transferred from the first vapor passage 51A is less likely to be disturbed, so it is possible to further efficiently send the working vapor 2a to the third vapor passage 51C. Thus, it is possible to cause heat from the vaporization region SR to go around uniformly in the plane of the vapor chamber 1.

As shown in FIG. 18(b), the first main body surface-side channel 70A may have a first main body surface-side main stream groove 71A and a pair of protrusions 74A located at both ends of the first main body surface-side main stream groove 71A in the width direction. Each protrusion 74A is located closer to the second main body surface 31b than the first main body surface 31a. In other words, the protrusions 74A are spaced apart from the lower sheet 10. In this case, a larger amount of working liquid 2b can be stored in the first main body surface-side channel 70A.

As shown in FIG. 18(c), the first main body surface-side channel 70A may have a flat surface 70s. The flat surface 70s is located closer to the second main body surface 31b than the first main body surface 31a. In other words, the flat surface 70s is spaced apart from the lower sheet 10. In this case, it is possible to further efficiently send the working vapor 2a to the third vapor passage 51C.

### Second Embodiment

Next, a second embodiment will be described with reference to FIGS. 19 to 36. FIGS. 19 to 36 are views showing the second embodiment. In FIGS. 19 to 36, like reference signs are assigned to the same portions as those of the first embodiment shown in FIGS. 1 to 18, and the detailed description is omitted.

A vapor chamber, a wick sheet for a vapor chamber, and an electronic apparatus according to the present embodiment will be described with reference to FIGS. 19 to 26. A vapor chamber 1 according to the present embodiment is a device mounted on an electronic apparatus E to cool devices D1, D2 serving as heat sources (heating elements) accommodated in the electronic apparatus E. The ones similar to the above-described device D may be used as the devices D1, D2.

As shown in FIG. 19, the electronic apparatus E (for example, a tablet terminal) includes the housing H, the plurality of (two in this case) devices D1, D2 accommodated in the housing H, and the vapor chamber 1. The vapor chamber 1 is accommodated in the housing H and is disposed in thermal contact with the devices D1, D2. With this configuration, the vapor chamber 1 can receive heat that is generated in the devices D1, D2 during use of the electronic apparatus E. The heat received by the vapor chamber 1 is released to outside the vapor chamber 1 via working fluids 2a, 2b (described later). In this way, the devices D1, D2 are effectively cooled. When the electronic apparatus E is a tablet terminal, the devices D1, D2 correspond to central processing units, or the like. In the present embodiment, the device D1 corresponds to a first heat source, and the device D2 corresponds to a second heat source.

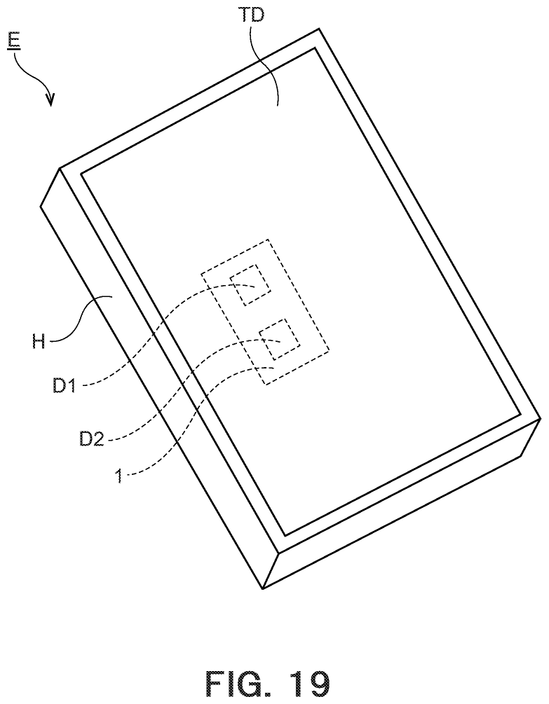

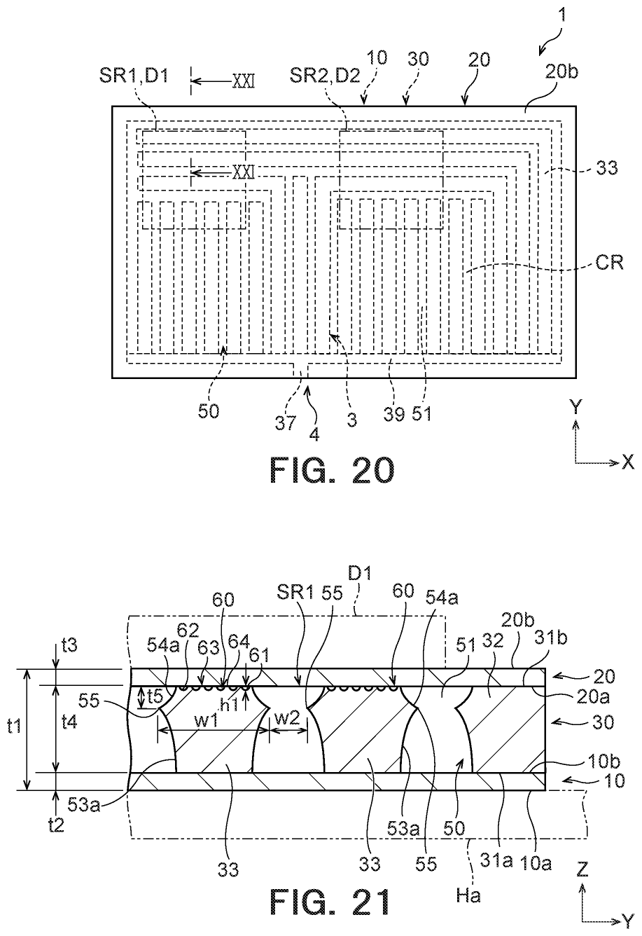

Next, the vapor chamber 1 according to the present embodiment will be described. As shown in FIGS. 20 and 21, the vapor chamber 1 includes a lower sheet 10 (first sheet), an upper sheet 20 (second sheet), and a wick sheet for a vapor chamber (hereinafter, simply referred to as wick sheet 30). The wick sheet 30 is interposed between the lower sheet 10 and the upper sheet 20.

As shown in FIG. 20, a first heat source region SR1 and a second heat source region SR2 (hereinafter also referred to as heat source regions SR1, SR2) that are regions where the working fluids 2a, 2b vaporize and a condensation region CR that is a region where the working fluids 2a, 2b condense are disposed on the wick sheet 30.

The first heat source region SR1 is a region that overlaps the device D1 that is the first heat source in a plan view and is a region in which the device D1 is attached. The second heat source region SR2 is a region that overlaps the device D2 that is the second heat source in a plan view and is a region in which the device D2 is attached. The heat source regions SR1, SR2 may be disposed in a selected place of the vapor chamber 1. In the present embodiment, the heat source regions SR1, SR2 are formed so as to be spaced apart from each other in the X direction. Heat from the device D1 is transferred to the heat source region SR1, and heat from the device D2 is transferred to the heat source region SR2. A liquid working fluid (referred to as working liquid 2b as needed) vaporizes in the heat source regions SR1, SR2 due to the heat. Therefore, the heat source regions SR1, SR2 make up a vaporization region where the working fluids 2a, 2b vaporize. Heat from the device D1 can be transferred not only to the region that overlaps the device D1 in a plan view but also to around the region. Heat from the device D2 can be transferred not only to the region that overlaps the device D2 in a plan view but also to around the region. Here, a plan view is a state viewed in a direction orthogonal to a surface that the vapor chamber 1 receives heat from the devices D1, D2 (the second upper sheet surface 20b of the upper sheet 20) and a surface that releases the received heat (the first lower sheet surface 10a of the lower sheet 10). In other words, a plan view, for example, corresponds to a state when the vapor chamber 1 is viewed from above as shown in FIG. 20 or a state when the vapor chamber 1 is viewed from below.

The condensation region CR is a region that does not overlap the devices D1, D2 in a plan view and is a region where the working vapor 2a mainly releases heat to condense. The condensation region CR may be regarded as a region present in a place apart from the heat source regions SR1, SR2 in the plane of the vapor chamber 1. Heat from the working vapor 2a is released to the lower sheet 10 in the condensation region CR, and the working vapor 2a is cooled in the condensation region CR to condense.

As shown in FIG. 21, the wick sheet 30 includes the vapor channel 50 and the liquid channels 60 disposed adjacent to the vapor channel 50. The wick sheet 30 has a first main body surface 31a and a second main body surface 31b on an opposite side to the first main body surface 31a. The first main body surface 31a is disposed adjacent to the lower sheet 10, and the second main body surface 31b is disposed adjacent to the upper sheet 20.

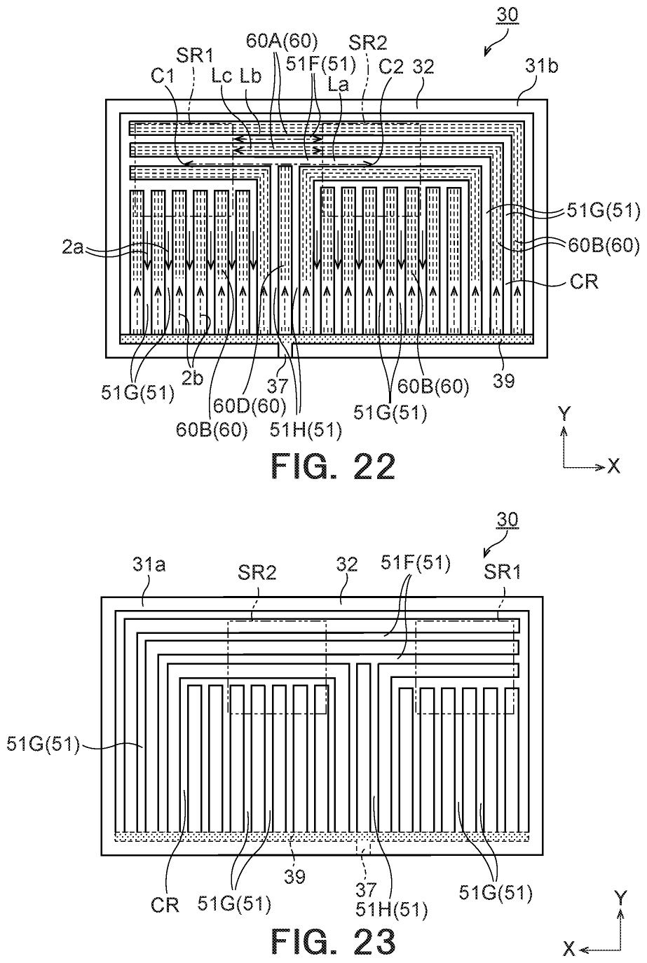

In the present embodiment, each of the lands 33 extends in a long-slender shape in a plan view. The planar shape of each land 33 may be a selected shape, such as a long-slender rectangular shape, a curved shape, including a circular arc, a U-shape, and an S-shape, and a bent line shape, including a V-shape and an L-shape. In FIGS. 22 and 23, the plurality of lands 33 includes lands extending in a straight line, L-shaped lands, and U-shaped lands in a plan view. Each of the lands 33 is disposed so as to be spaced apart from the other lands 33 in a width direction of the lands 33. A working vapor 2a is configured to flow around the lands 33 so as to be transferred toward the condensation region CR. Thus, interference with the flow of working vapor 2a is suppressed. The width w1 (see FIG. 21) of the land 33 may be, for example, greater than or equal to 30 μm and less than or equal to 3000 μm. Here, the width w1 of the land 33 is the dimension of the land 33 in a direction orthogonal to an extension direction of the land 33 (width direction) and means a dimension at a position where the land 33 is the widest (for example, a position where a protrusion 55 is present).

As shown in FIGS. 22 and 23, in the present embodiment, the plurality of vapor passages 51 includes coupling vapor passages 51F, sole vapor passages 51G, and branched vapor passages 51H. The coupling vapor passages 51F, the sole vapor passages 51G, and the branched vapor passages 51h each are a channel through which the working vapor 2a passes and each are formed between the plurality of lands 33 or between the frame 32 and the lands 33. The basic configuration, such as the sectional shape, of each of the coupling vapor passages 51F, the sole vapor passages 51G, and the branched vapor passages 51H is the same as the configuration of the above-described vapor passage 51. The coupling vapor passages 51F, the sole vapor passages 51G, and the branched vapor passages 51H each may extend in a straight line or may have a selected shape, such as a curved shape, including a circular arc and an S-shape, and a bent line shape, such as a V-shape and an L-shape. In the specification, the coupling vapor passages 51F, the sole vapor passages 51G, and the branched vapor passages 51H are collectively simply referred to as vapor passages 51.

Each of the coupling vapor passages 51F is a vapor channel that connects the first heat source region SR1 and the second heat source region SR2 with each other. In other words, one end of the coupling vapor passage 51F in the extension direction overlaps the first heat source region SR1 and the other end of the coupling vapor passage 51F in the extension direction overlaps the second heat source region SR2. In the coupling vapor passage 51F, the working vapor 2a is flowed between the first heat source region SR1 side and the second heat source region SR2 side. Particularly, when the device D1 is being driven and the device D2 is stopped, the working vapor 2a flows from the first heat source region SR1 side toward the second heat source region SR2 side by the coupling vapor passages 51F. Particularly, when the device D1 is being driven and the device D2 is stopped, the working vapor 2a flows from the first heat source region SR1 side toward the second heat source region SR2 side by the coupling vapor passages 51F.

Each of the sole vapor passages 51G is a vapor channel that is connected to any one of the first heat source region SR1 and the second heat source region SR2 and not connected to the other. In other words, one end of the sole vapor passage 51G in the extension direction overlaps the first heat source region SR1 or the second heat source region SR2, and the other end of the sole vapor passage 51G in the extension direction does not overlap the first heat source region SR1 or the second heat source region SR2. The other end of the sole vapor passage 51G in the extension direction is preferably present in the condensation region CR at a position away from the heat source regions SR1, SR2 outward in the plane direction and may, for example, terminate at a supporting portion 39 (described later). In the sole vapor passage 51G, the working vapor 2a flows from the first heat source region SR1 or the second heat source region SR2 outward in the plane direction. Particularly, the working vapor 2a flows from the heat source region SR1 or the heat source region SR2, corresponding to the device D1 or device D2 being driven, outward in the plane direction. In the wick sheet 30, the sole vapor passage 51G connected to any one of the heat source regions SR1, SR2 may be provided, and the sole vapor passage 51G connected to the other does not need to be provided.

Each of the branched vapor passages 51H is a vapor channel connected midway to the coupling vapor passage 51F in the extension direction and is a vapor channel that does not overlap any of the heat source regions SR1, SR2. In other words, one end of the branched vapor passage 51H in the extension direction is connected to the coupling vapor passage 51F, and the other end of the branched vapor passage 51H in the extension direction is present at a position other than the heat source regions SR1, SR2. The other end of the branched vapor passage 51H in the extension direction is preferably present in the condensation region CR at a position away from the heat source regions SR1, SR2 outward in the plane direction and may, for example, terminate at the supporting portion 39 (described later). Alternatively, the other end of the branched vapor passage 51H in the extension direction may be connected to another one of the vapor passages 51. In the branched vapor passage 51H, the working vapor 2a flows from the coupling vapor passage 51F side outward in the plane direction. Particularly, when the device D1 is being driven and the device D2 is stopped, the working vapor 2a flows from the first heat source region SR1 side outward in the plane direction by the coupling vapor passages 51F and the branched vapor passages 51H. On the other hand, when the device D1 is stopped and the device D2 is being driven, the working vapor 2a flows from the second heat source region SR2 side outward in the plane direction by the coupling vapor passages 51F and the branched vapor passages 51H. When the devices D1, D2 both are being driven, the working vapor 2a flows from the heat source regions SR1, SR2 side outward in the plane direction by the coupling vapor passages 51F and the branched vapor passages 51H. The branched vapor passages 51H do not need to be provided in the wick sheet 30. When another heat source region (for example, a third heat source region SR3 (described later)) is provided, the branched vapor passages 51H may overlap another heat source region.

As shown in FIGS. 22 and 23, the supporting portion 39 that supports the ends of the lands 33 in the extension direction on the frame 32 is provided in the vapor channel 50. The supporting portion 39 may support adjacent two of the lands 33 or may support one of the lands 33. The supporting portion 39 is provided along one side (in this case, one side located on the negative side in the Y direction) of the frame 32. The supporting portion 39 may be provided in part or whole of a side that is a component of the frame 32. The supporting portion 39 is preferably formed so as not to impede flow of the working vapor 2a that diffuses in the vapor channel 50. In this case, the supporting portion 39 is disposed adjacent to the first main body surface 31a of the wick sheet 30, and a space that communicates with the vapor channel 50 is formed adjacent to the second main body surface 31b. In FIGS. 22 and 23, the supporting portion 39 is indicated in gray. The supporting portion 39 is thinned by half-etching from the second main body surface 31b side. The supporting portion 39 is a region that does not extend through the wick sheet 30 in the thickness direction and is less in thickness than the frame 32. Thus, the thickness of the supporting portion 39 may be made thinner than the thickness of the wick sheet 30, so it is possible to suppress separation of the vapor channel 50 due to the supporting portion 39. However, the configuration is not limited thereto. The supporting portion 39 may be disposed adjacent to the second main body surface 31b. A space that communicates with the vapor channel 50 may be formed on each of the first main body surface 31a-side surface and second main body surface 31b-side surface of the supporting portion 39.

As shown in FIG. 22, in the present embodiment, the plurality of liquid channels 60 each includes coupling liquid channels 60A, sole liquid channels 60B, and independent liquid channels 60D. The coupling liquid channels 60A, the sole liquid channels 60B, and the independent liquid channels 60D all are channels through which the working liquid 2b passes and are formed on the lands 33. The basic configuration, such as the sectional shape, of each of the coupling liquid channels 60A, the sole liquid channels 60B, and the independent liquid channels 60D is the same as the configuration of the liquid channel 60 according to the first embodiment. The coupling liquid channels 60A, the sole liquid channels 60B, and the independent liquid channels 60D respectively extend linearly along the shapes of the lands 33. In the specification, the coupling liquid channels 60A, the sole liquid channels 60B, and the independent liquid channels 60D are collectively simply referred to as liquid channels 60.

Each of the coupling liquid channels 60A is a liquid channel that connects the first heat source region SR1 and the second heat source region SR2 with each other. In other words, one end of the coupling liquid channel 60A in the extension direction overlaps the first heat source region SR1 and the other end of the coupling liquid channel 60A in the extension direction overlaps the second heat source region SR2. In the coupling liquid channel 60A, the working liquid 2b is flowed between the first heat source region SR1 side and the second heat source region SR2 side. Particularly, when the device D1 is being driven and the device D2 is stopped, the working liquid 2b flows from the second heat source region SR2 side toward the first heat source region SR1 side by the coupling liquid channels 60A. On the other hand, when the device D1 is stopped and the device D2 is being driven, the working liquid 2b flows from the first heat source region SR1 side toward the second heat source region SR2 side by the coupling liquid channels 60A.

Each of the sole liquid channels 60B is a liquid channel that is connected to any one of the first heat source region SR1 and the second heat source region SR2 and not connected to the other. In other words, one end of the sole liquid channel 60B in the extension direction overlaps the first heat source region SR1 or the second heat source region SR2, and the other end of the sole liquid channel 60B in the extension direction does not overlap the first heat source region SR1 or the second heat source region SR2. The other end of the sole liquid channel 60B in the extension direction is preferably present in the condensation region CR at a position away from the heat source regions SR1, SR2 outward in the plane direction and may, for example, terminate at the supporting portion 39. In the sole liquid channel 60B, the working liquid 2b flows from the condensation region CR, located outward in the plane direction, toward the first heat source region SR1 or the second heat source region SR2. Particularly, the working liquid 2b flows from the condensation region CR toward the heat source region SR1 corresponding to the device D1 or the heat source region SR2 corresponding to the device D2, being driven. In the wick sheet 30, the sole liquid channel 60B connected to any one of the heat source regions SR1, SR2 may be provided, and the sole liquid channel 60B connected to the other does not need to be provided.

Each of the independent liquid channels 60D is a liquid channel that is not connected to the other liquid channels 60 (the coupling liquid channels 60A, the sole liquid channels 60B, and the like) and that does not overlap any of the heat source regions SR1, SR2. In other words, both ends of the independent liquid channel 60D in the extension direction are present at a position other than the other liquid channels 60 and other than the heat source regions SR1, SR2. One end of the independent liquid channel 60D in the extension direction is preferably present in the condensation region CR at a position away from the heat source regions SR1, SR2 outward in the plane direction and may, for example, terminate at the above-described supporting portion 39. In the independent liquid channel 60D, the working liquid 2b flows from outside in the plane direction toward the heat source regions SR1, SR2. The independent liquid channels 60D do not need to be provided in the wick sheet 30.

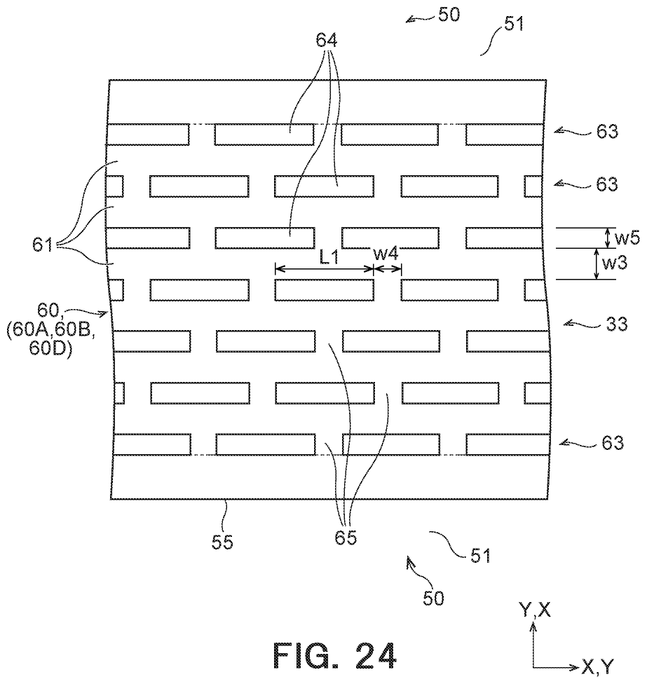

FIG. 24 is an enlarged view showing the upper surface of the liquid channel 60 (the coupling liquid channel 60A, the sole liquid channel 60B, or the independent liquid channel 60D). As shown in FIG. 24, the working liquid 2b passes through the liquid channel 60, and the liquid channel 60 has a plurality of liquid channel main stream grooves 61 disposed parallel to one another, and a plurality of liquid channel communication grooves 65 that communicate with the liquid channel main stream grooves 61. In the example shown in FIG. 24, each land 33 includes six liquid channel main stream grooves 61; however, the configuration is not limited thereto. The number of the liquid channel main stream grooves 61 included in each land 33 is selectable and may be, for example, greater than or equal to three and less than or equal to 20.

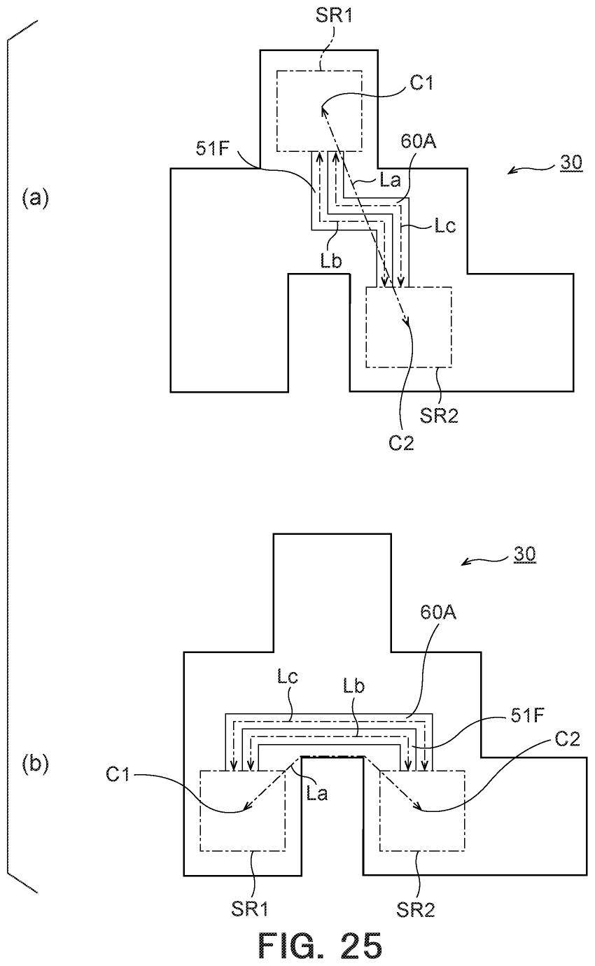

Next, the arrangement relationship among the first heat source region SR1, the second heat source region SR2, the coupling vapor passage 51F, and the coupling liquid channel 60A will be described with reference to FIGS. 25(a) and 25(b). FIGS. 25(a) and 25(b) are schematic top views of the wick sheet 30. In FIGS. 25(a) and 25(b), for the sake of convenience, elements other than the first heat source region SR1, the second heat source region SR2, the coupling vapor passage 51F, and the coupling liquid channel 60A are not shown.

As shown in FIG. 25(a), the first heat source region SR1 and the second heat source region SR2 are disposed on the wick sheet 30 so as to be spaced apart from each other. In this case, a center-to-center distance between the first heat source region SR1 and the second heat source region SR2 is indicated by La. The center-to-center distance La is a shortest distance on the wick sheet 30 between the center C1 of the first heat source region SR1 and the center C2 of the second heat source region SR2. In FIG. 25(a), the center-to-center distance La is equal to the length of a line segment connecting the center C1 with the center C2. The center C1 of the first heat source region SR1 and the center C2 of the second heat source region SR2 may be respectively the center of gravity of the first heat source region SR1 and the center of gravity of the second heat source region SR2.

As shown in FIG. 25(b), it is presumable that the line segment connecting the center C1 of the first heat source region SR1 with the center C2 of the second heat source region SR2 deviates from the plane of the wick sheet 30. In this case, the center-to-center distance La means the length of a shortest-distance line passing through the plane of the wick sheet 30 among lines connecting the center C1 with the center C2.

In FIG. 25(a), the first heat source region SR1 and the second heat source region SR2 are connected to each other by the coupling vapor passage 51F and the coupling liquid channel 60A. In this case, the length of the coupling vapor passage 51F and the length of the coupling liquid channel 60A are respectively indicated by Lb and Lc. The length Lb of the coupling vapor passage 51F means the length of a line connecting the centers of the coupling vapor passage 51F in the width direction in a region that does not overlap the heat source regions SR1, SR2. The length Lc of the coupling liquid channel 60A means the length of a line connecting the centers of the coupling liquid channel 60A in the width direction in a region that does not overlap the heat source regions SR1, SR2.

At this time, the length Lb of the coupling vapor passage 51F is preferably less than or equal to twice the center-to-center distance La (Lb<2La). When the length Lb of the coupling vapor passage 51F is less than or equal to twice the center-to-center distance La, a part in the middle of the coupling vapor passage 51F is not excessively away from the heat source regions SR1, SR2. Thus, it is possible to reduce a situation in which the working vapor 2a condenses into the working liquid 2b midway in the coupling vapor passage 51F.

Similarly, the length Lc of the coupling liquid channel 60A is preferably less than or equal to twice the center-to-center distance La (Lc<2La). When the length Lc of the coupling liquid channel 60A is less than or equal to twice the center-to-center distance La, a part in the middle of the coupling liquid channel 60A is not excessively away from the heat source regions SR1, SR2. Thus, it is possible to reduce a situation in which the working vapor 2a condenses into the working liquid 2b in the coupling vapor passage 51F adjacent to the coupling liquid channel 60A at a position away from the heat source regions SR1, SR2.

As shown in FIG. 22, the length Lb of the coupling vapor passage 51F and the length Lc of the coupling liquid channel 60A each may be less than or equal to once the center-to-center distance La between the first heat source region SR1 and the second heat source region SR2.

In the present embodiment, the first heat source region SR1 and the second heat source region SR2 are connected to each other by at least one coupling vapor passage 51F and at least one coupling liquid channel 60A. However, the configuration is not limited thereto. For example, the first heat source region SR1 and the second heat source region SR2 may be connected to each other by at least one coupling vapor passage 51F and do not need to be connected to each other by the coupling liquid channel 60A. Alternatively, the first heat source region SR1 and the second heat source region SR2 may be connected to each other by at least one coupling liquid channel 60A and do not need to be connected to each other by the coupling vapor passage 51F.

The vapor chamber 1 and the wick sheet 30 according to the present embodiment can be manufactured substantially similarly to the case of the first embodiment (see FIG. 10).

An operation method for the vapor chamber 1 according to the present embodiment is substantially similar to the case of the first embodiment except that the plurality of devices D1, D2 is provided.

In the present embodiment, the plurality of (two) devices D1, D2 is attached to the vapor chamber 1. In this case, two of the devices D1, D2 can be driven at the same time or only any one of the devices D1, D2 can be driven.

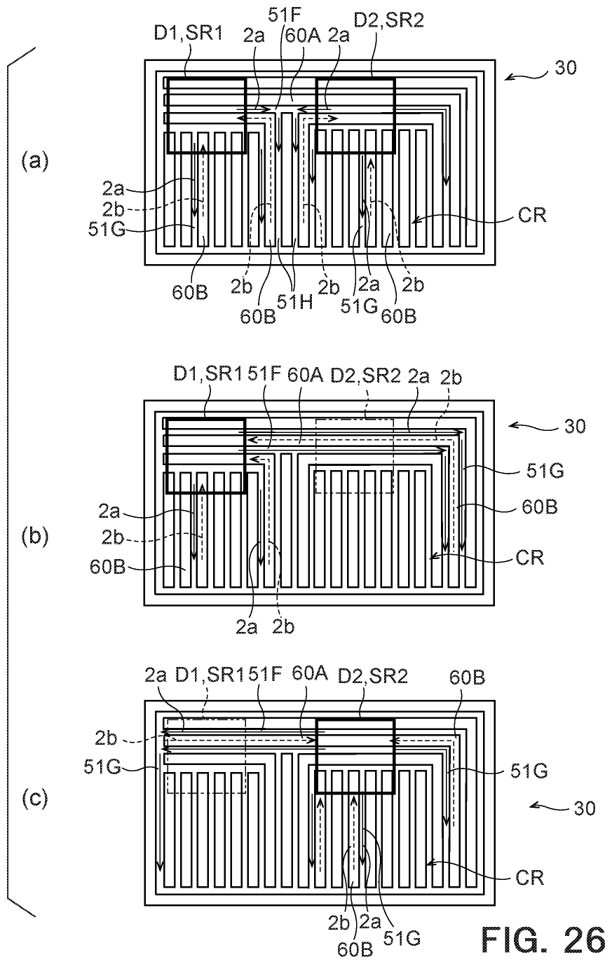

FIGS. 26(a) to 26(c) respectively show a case where both the devices D1, D2 are being driven in the wick sheet 30 shown in FIG. 22 (FIG. 26(a)), a case where only the device D1 is being driven (FIG. 26(b)), and a case where only the device D2 is being driven (FIG. 26a(c)). In FIGS. 26(a) to 26(c), the heat source regions SR1, SR2 corresponding to the devices D1, D2, being driven, are indicated by the wide line, and the heat source regions SR1, SR2 corresponding to the devices D1, D2, not being driven, are indicated by the alternate long and two-short dashed line.

As shown in FIG. 26(a), when both the devices D1, D2 are being driven, the working vapor 2a produced from the heat source regions SR1, SR2 is transferred from the heat source regions SR1, SR2 side sequentially via the coupling vapor passages 51F and the branched vapor passages 51H to the condensation region CR side. After that, the working vapor 2a changes into the working liquid 2b in the condensation region CR, and the working liquid 2b is returned to the heat source regions SR1, SR2 side via the sole liquid channels 60B.

Alternatively, part of the working vapor 2a produced from the heat source regions SR1, SR2 is transferred to the condensation region CR side via the sole vapor passages 51G extending from the heat source regions SR1, SR2. After that, the working vapor 2a changes into the working liquid 2b in the condensation region CR, and the working liquid 2b is returned to the heat source regions SR1, SR2 side via the sole liquid channels 60B.

As shown in FIG. 26(b), when only the device D1 is being driven, the working vapor 2a produced from the first heat source region SR1 passes through the second heat source region SR2 from the coupling vapor passages 51F and is transferred to the condensation region CR side via the sole vapor passages 51G extending from the second heat source region SR2. After that, the working vapor 2a changes into the working liquid 2b in the condensation region CR, the working liquid 2b passes through the second heat source region SR2 from the sole liquid channels 60B extending from the second heat source region SR2, and is returned to the first heat source region SR1 side via the coupling liquid channels 60A.

Alternatively, part of the working vapor 2a produced from the first heat source region SR1 is transferred to the condensation region CR side via the sole vapor passages 51G extending from the first heat source region SR1. After that, the working vapor 2a changes into the working liquid 2b in the condensation region CR, and the working liquid 2b is returned to the first heat source region SR1 side via the sole liquid channels 60B extending from the first heat source region SR1.

As shown in FIG. 26(c), when only the device D2 is being driven, the working vapor 2a produced from the second heat source region SR2 passes through the first heat source region SR1 from the coupling vapor passages 51F and is transferred to the condensation region CR side via the sole vapor passages 51G extending from the first heat source region SR1. After that, the working vapor 2a changes into the working liquid 2b in the condensation region CR, the working liquid 2b passes through the first heat source region SR1 from the sole liquid channels 60B extending from the first heat source region SR1, and is returned to the second heat source region SR2 side via the coupling liquid channels 60A.

Alternatively, part of the working vapor 2a produced from the second heat source region SR2 is transferred to the condensation region CR side via the sole vapor passages 51G extending from the second heat source region SR2. After that, the working vapor 2a changes into the working liquid 2b in the condensation region CR, and the working liquid 2b is returned to the second heat source region SR2 side via the sole liquid channels 60B extending from the second heat source region SR2.

In this way, according to the present embodiment, the first heat source region SR1 and the second heat source region SR2 are connected to each other by at least one coupling vapor passage 51F. Thus, when only one device D1 (D2) is being driven, the working vapor 2a produced from the heat source region SR1 (SR2) corresponding to the device D1 (D2) being driven can be transferred to the condensation region CR side via the coupling vapor passage 51F. The first heat source region SR1 and the second heat source region SR2 are connected to each other by at least one coupling liquid channel 60A. Therefore, when only the device D1 (D2) is being driven, the working liquid 2b produced in the condensation region CR can be returned to the first heat source region SR1 (the second heat source region SR2) side via the coupling liquid channel 60A. Thus, not only when both the devices D1, D2 are being driven but also when only one device D1 (D2) is being driven, the working vapor 2a can be transferred in a direction away from the heat sources, and the condensed working liquid 2b can be returned to the heat source side. As a result, a region where heat is less likely to be transferred in the plane of the vapor chamber 1 can be reduced, and a wide range of the vapor chamber 1 can be used to transfer heat, so it is possible to cause heat from the heat sources to go around uniformly in the plane of the vapor chamber 1.

According to the present embodiment, the vapor passages 51 include the sole vapor passages 51G each connected to any one of the first heat source region SR1 and the second heat source region SR2 and not connected to the other. Thus, the working vapor 2a produced from the heat source region SR1 (SR2) corresponding to the device D1 (D2) being driven can be transferred to the condensation region CR side via the sole vapor passages 51G.

According to the present embodiment, the vapor passages 51 include the branched vapor passages 51H connected midway to the coupling vapor passage 51F. Thus, when both the devices D1, D2 are being driven, the working vapor 2a produced from the heat source regions SR1, SR2 can be transferred to the condensation region CR side sequentially via the coupling vapor passage 51F and the branched vapor passages 51H.

According to the present embodiment, the liquid channels 60 include the sole liquid channels 60B each connected to any one of the first heat source region SR1 and the second heat source region SR2 and not connected to the other. Thus, it is possible to return the working liquid 2b condensed in the condensation region CR to the first heat source region SR1 or the second heat source region SR2 side via the sole liquid channels 60B.

### (Modifications of Wick Sheet)

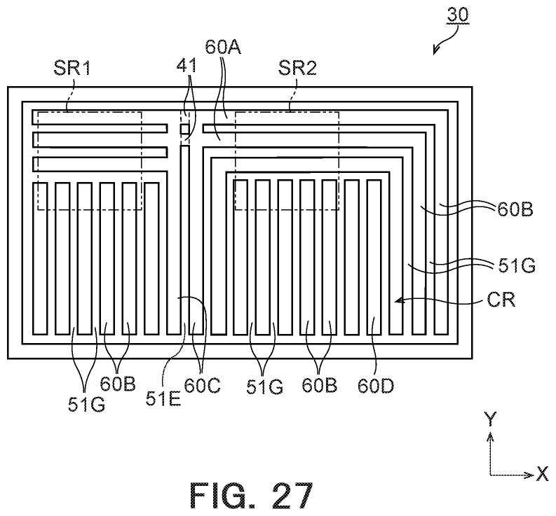

Next, various modifications of the wick sheet according to the second embodiment will be described with reference to FIGS. 27 to 35. FIGS. 27 to 35 are enlarged top views respectively showing the wick sheets 30 according to the modifications. In FIGS. 27 to 35, like reference signs are assigned to the same portions as those of the embodiment shown in FIGS. 19 to 26, and the detailed description is omitted.

### (First Modification of Wick Sheet)

As shown in FIG. 27, the first heat source region SR1 and the second heat source region SR2 are connected to each other by the coupling liquid channels 60A. On the other hand, in FIG. 27, the first heat source region SR1 and the second heat source region SR2 are not connected to each other by the coupling vapor passage 51F.

The branched liquid channels 60C are connected midway to the coupling liquid channels 60A in the extension direction. Each of the branched liquid channels 60C is a liquid channel connected to the coupling liquid channels 60A and is a liquid channel that does not overlap any of the heat source regions SR1, SR2. When the branched liquid channels 60C are provided in this way, the working liquid 2b condensed in the condensation region CR can be returned to the heat source regions SR1, SR2 side sequentially via the branched liquid channels 60C and the coupling liquid channels 60A.

Furthermore, a bridge 41 is formed midway in each of the coupling liquid channels 60A in the extension direction. The bridge 41 is thinned from the back surface (first main body surface 31a) side. The thinned part of the bridge 41 communicates with the vapor passage 51E that intersects with the coupling liquid channels 60A. With the bridge 41, it is possible to ensure the flow of working liquid 2b by the coupling liquid channels 60A located adjacent to the surface (second main body surface 31b) and not to interfere with the flow of working vapor 2a in the vapor passage 51E located adjacent to the back surface side.

### (Second Modification of Wick Sheet)

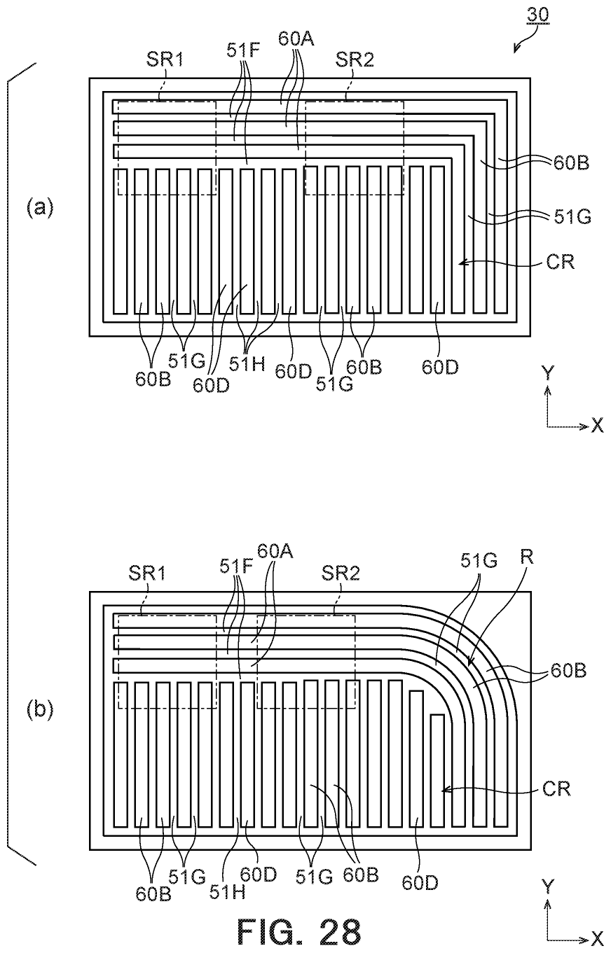

In FIGS. 28(a) and 28(b), the first heat source region SR1 and the second heat source region SR2 are connected to each other by the plurality of coupling vapor passages 51F and the plurality of coupling liquid channels 60A, and the branched vapor passages 51H are connected to one or some of the coupling vapor passages 51F. The independent liquid channels 60D are disposed adjacent to the branched vapor passages 51H. The independent liquid channels 60D extend parallel to the plurality of sole liquid channels 60B respectively extending from the heat source regions SR1, SR2. When the independent liquid channels 60D are disposed, recovery of the working liquid 2b in the plane of the wick sheet 30 is easy.

As shown in FIG. 28(a), the plurality of branched vapor passages 51H may be connected to one or some of the coupling vapor passages 51F. Thus, particularly, when both the devices D1, D2 are being driven, it is possible to cause the working vapor 2a to efficiently flow from the heat source regions SR1, SR2 side toward the condensation region CR side by the plurality of branched vapor passages 51H.

As shown in FIG. 28(b), one or some of the sole vapor passages 51G extending from the second heat source region SR2 may have a curved part R that is formed in a curved shape in a plan view. The sole liquid channels 60B adjacent to the sole vapor passages 51G are also formed in a curved shape in a plan view as in the case of the sole vapor passages 51G. When the sole vapor passages 51G have the curved part R, it is possible to reduce the vapor resistance of the working vapor 2a flowing through the sole vapor passages 51G and to easily transfer heat in the plane of the vapor chamber 1. Not limited to the sole vapor passages 51G, the coupling vapor passages 51F or the branched vapor passages 51H may be formed in a curved shape in a plan view.

### (Third Modification of Wick Sheet)

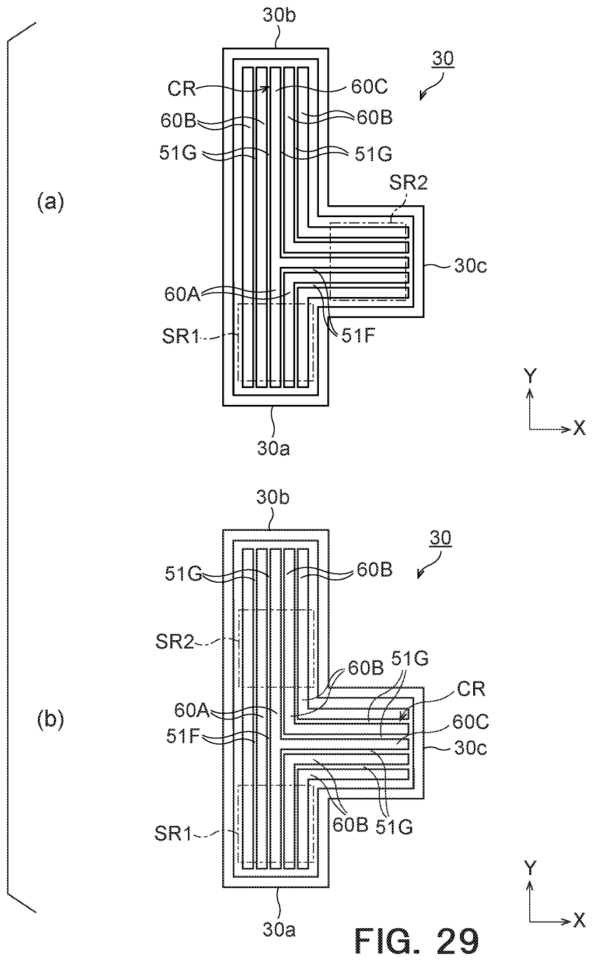

As shown in FIGS. 29(a) and 29(b), the wick sheet 30 may have a T-shape in a plan view. In this case, the wick sheet 30 has a first end 30a, a second end 30b on an opposite side to the first end 30a, and a third end 30c located in a transverse direction with respect to the first end 30a and the second end 30b.

In FIG. 29(a), the first heat source region SR1 is located adjacent to the first end 30a, and the second heat source region SR2 is located adjacent to the third end 30c. The condensation region CR is located adjacent to the second end 30b. The first heat source region SR1 and the second heat source region SR2 are connected to each other by the coupling vapor passages 51F having an L-shape in a plan view and the coupling liquid channels 60A having an L-shape in a plan view. The branched liquid channel 60C is connected midway to one or some of the coupling liquid channels 60A. The sole vapor passages 51G having a straight line shape in a plan view and the sole liquid channels 60B having a straight line shape in a plan view are connected to the first heat source region SR1. The sole vapor passages 51G having an L-shape in a plan view and the sole liquid channels 60B having an L-shape in a plan view are connected to the second heat source region SR2.

In FIG. 29(b), the first heat source region SR1 is located adjacent to the first end 30a, and the second heat source region SR2 is located adjacent to the second end 30b. The condensation region CR is located adjacent to the third end 30c. The first heat source region SR1 and the second heat source region SR2 are connected to each other by the coupling vapor passages 51F having a straight line shape in a plan view and the coupling liquid channels 60A having a straight line shape in a plan view. The branched liquid channel 60C is connected midway to one or some of the coupling liquid channels 60A. The sole vapor passages 51G having an L-shape in a plan view and the sole liquid channels 60B having an L-shape in a plan view are connected to the first heat source region SR1. The sole vapor passages 51G having an L-shape in a plan view, the sole liquid channels 60B having an L-shape in a plan view, the sole vapor passages 51G having a straight line shape in a plan view, and the sole liquid channels 60B having a straight line shape in a plan view are connected to the second heat source region SR2.

According to the present modification, when only the device D1 (D2) is being driven, the working vapor 2a can be transferred to the device D2 (D1) side not being driven. In other words, the region in which the device D2 (D1) is not being driven can be used as the condensation region CR. Thus, a wide range in the plane of the vapor chamber 1 can be used to transfer heat, so it is possible to cause heat from the heat sources to go around uniformly in the plane of the vapor chamber 1.

### (Fourth Modification of Wick Sheet)

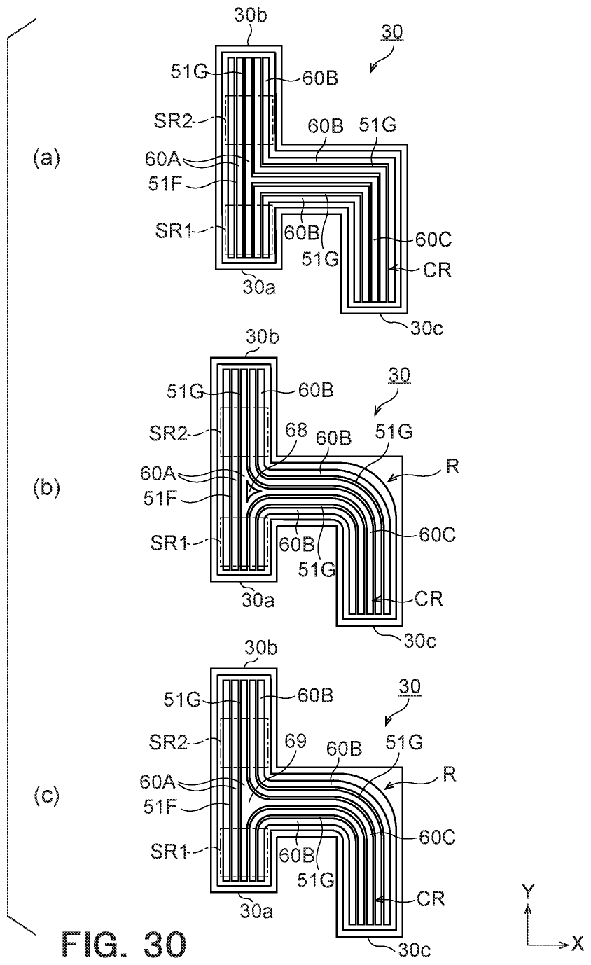

As shown in FIGS. 30(a) to 30(c), the wick sheet 30 may have a substantially h-shape in a plan view. In this case, the wick sheet 30 has a first end 30a, a second end 30b on an opposite side to the first end 30a, and a third end 30c located in a transverse direction with respect to the first end 30a and the second end 30b. In FIGS. 30(a) to 30(c), the first heat source region SR1 is located adjacent to the first end 30a, and the second heat source region SR2 is located adjacent to the second end 30b. The condensation region CR is located adjacent to the third end 30c.

In FIGS. 30(a) to 30(c), the first heat source region SR1 and the second heat source region SR2 are connected to each other by the coupling vapor passages 51F having a straight line shape in a plan view and the coupling liquid channels 60A having a straight line shape in a plan view. The branched liquid channel 60C is connected midway to one or some of the coupling liquid channels 60A. The sole vapor passages 51G and the sole liquid channels 60B are connected to the first heat source region SR1. Furthermore, the sole vapor passages 51G and the sole liquid channels 60B are connected to the second heat source region SR2.

In FIG. 30(a), the sole vapor passages 51G, the sole liquid channels 60B, and the branched liquid channel 60C extending from the heat source regions SR1, SR2 to the third end 30c side each have a bent part that is bent at a right angle in a plan view.

In FIG. 30(b), the sole vapor passages 51G, the sole liquid channels 60B, and the branched liquid channel 60C extending from the heat source regions SR1, SR2 to the third end 30c side each have a curved part R that is formed in a curved shape in a plan view. Thus, it is possible to reduce the vapor resistance of the working vapor 2a flowing through the sole vapor passages 51G and to easily transfer heat in the plane of the vapor chamber 1. A connecting part between the branched liquid channel 60C and the coupling liquid channel 60A is curved, and a connecting recess 68 with no liquid channel is present at the connecting part. The connecting recess 68 has a substantially triangular shape in a plan view; however, the configuration is not limited thereto. The connecting recess 68 may have a planar shape according to the shapes of the branched liquid channel 60C and coupling liquid channel 60A located therearound. Thus, it is possible to suppress stagnation of the working liquid 2b at the connecting part between the branched liquid channel 60C and the coupling liquid channel 60A. When the vapor chamber 1 is put in an environment lower in temperature than the freezing point of the working liquid 2b, it is possible to avoid freezing of the working liquid 2b remaining on the connecting part and breakage of the vapor chamber 1.

In FIG. 30(c), a connecting part between the branched liquid channel 60C and the coupling liquid channel 60A is curved, and a connecting liquid channel 69 with a liquid channel is present at the connecting part. The connecting liquid channel 69 has a substantially triangular shape in a plan view; however, the configuration is not limited thereto. The connecting liquid channel 69 may have a planar shape according to the shapes of the branched liquid channel 60C and coupling liquid channel 60A located therearound. Thus, it is possible to cause the working liquid 2b from the branched liquid channel 60C to easily flow toward the coupling liquid channel 60A via the connecting liquid channel 69. The remaining configuration is similar to the configuration shown in FIG. 30(b).

### (Fifth Modification of Wick Sheet)

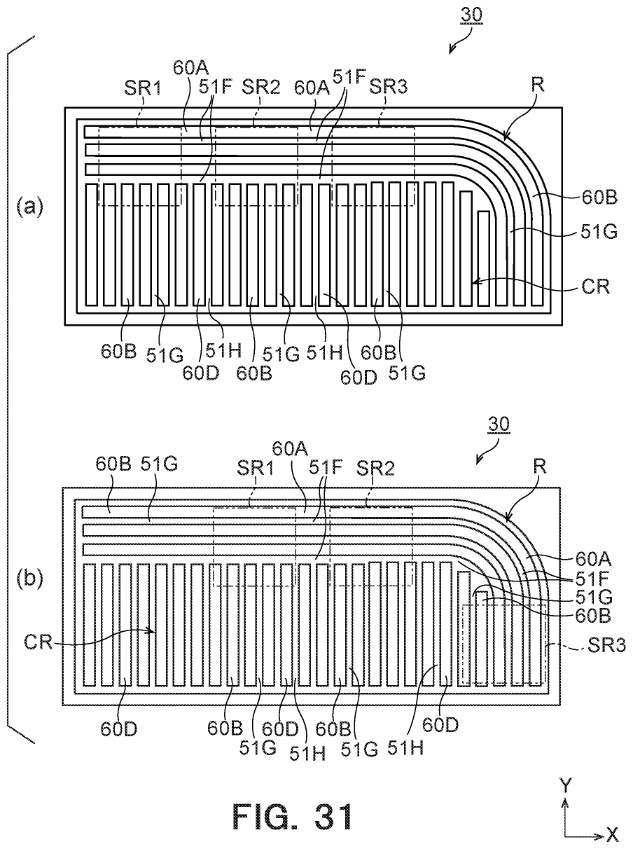

As shown in FIGS. 31(a) and 31(b), not only the first heat source region SR1 and the second heat source region SR2 but also a third heat source region SR3 is disposed on the wick sheet 30. A device D3 that is a third heat source is disposed in the third heat source region SR3. In FIGS. 31(a) and 31(b), the first heat source region SR1, the second heat source region SR2, and the third heat source region SR3 are disposed in order from the negative side in the X direction; however, the positional relationship among the heat source regions SR1, SR2, SR3 is not limited thereto.

In FIGS. 31(a) and 31(b), the first heat source region SR1 and the second heat source region SR2 are connected to each other by the coupling vapor passages 51F and the coupling liquid channels 60A. The branched vapor passages 51H are connected midway to one or some of the coupling vapor passages 51F. The sole vapor passages 51G and the sole liquid channels 60B are connected to the first heat source region SR1, and the sole vapor passages 51G and the sole liquid channels 60B are connected to the second heat source region SR2. The first heat source region SR1 and the second heat source region SR2 may be connected by one of the set of coupling vapor passages 51F and the set of coupling liquid channels 60A.

The second heat source region SR2 and the third heat source region SR3 are connected to each other by the coupling vapor passages 51F and the coupling liquid channels 60A. The branched vapor passages 51H are connected midway to one or some of the coupling vapor passages 51F. The sole vapor passages 51G and the sole liquid channels 60B are connected to the third heat source region SR3. The second heat source region SR2 and the third heat source region SR3 may be connected by one of the set of coupling vapor passages 51F and the set of coupling liquid channels 60A.

The independent liquid channels 60D are disposed adjacent to the branched vapor passages 51H. The independent liquid channels 60D extend parallel to the sole liquid channels 60B respectively extending from the heat source regions SR1, SR2, SR3. When the independent liquid channels 60D are disposed, recovery of the working liquid 2b in the plane of the wick sheet 30 is easy.

In FIG. 31(a), some of the sole vapor passages 51G extending from the third heat source region SR3 have a curved part R that is formed in a curved shape in a plan view. The sole liquid channels 60B adjacent to the sole vapor passages 51G are also formed in a curved shape in a plan view as in the case of the sole vapor passages 51G. When the sole vapor passages 51G have the curved part R, it is possible to reduce the vapor resistance of the working vapor 2a flowing through the sole vapor passages 51G and to easily transfer heat in the plane of the vapor chamber 1.

In FIG. 31(b), the coupling vapor passages 51F that connect the second heat source region SR2 with the third heat source region SR3 may have a curved part R that is formed in a curved shape in a plan view. The coupling liquid channels 60A adjacent to the coupling vapor passages 51F are also formed in a curved shape in a plan view as in the case of the coupling vapor passages 51F. When the coupling vapor passages 51F have the curved part R, it is possible to reduce the vapor resistance of the working vapor 2a flowing through the coupling vapor passages 51F and to easily transfer heat in the plane of the vapor chamber 1.

According to the present modification, when any one or two of the three devices D1 to D3 are being driven, the working vapor 2a can be transferred to the device side not being driven. Thus, a wide range in the plane of the vapor chamber 1 can be used to transfer heat, so it is possible to cause heat from the heat sources to go around uniformly in the plane of the vapor chamber 1. Four or more heat source regions may be disposed on the wick sheet 30.

### (Sixth Modification of Wick Sheet)

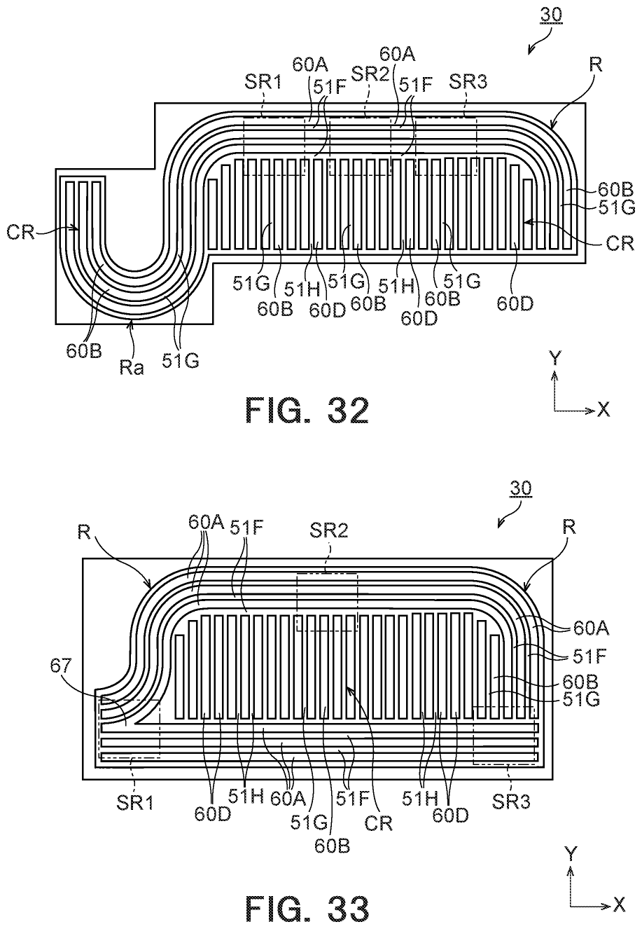

As shown in FIG. 32, the first heat source region SR1, the second heat source region SR2, and the third heat source region SR3 are disposed on the wick sheet 30. In this case, some of the sole vapor passages 51G connected to the first heat source region SR1 have a curved part Ra that is curved in a U-shape in a plan view. At the curved part Ra, the direction of flow of the sole vapor passages 51G is inverted by 180°. The sole liquid channels 60B adjacent to the sole vapor passages 51G are also curved in a U-shape in a plan view as in the case of the sole vapor passages 51G. When the sole vapor passages 51G have the curved part Ra that is curved in a U-shape, the working vapor 2a can be transferred to a position away from the heat source regions SR1, SR2, SR3.

The branched vapor passages 51H are connected midway to one or some of the coupling vapor passages 51F. The independent liquid channels 60D are disposed adjacent to the branched vapor passages 51H. The independent liquid channels 60D extend parallel to the plurality of sole liquid channels 60B respectively extending from the heat source regions SR1, SR2, SR3. When the independent liquid channels 60D are disposed, recovery of the working liquid 2b in the plane of the wick sheet 30 is easy.

### (Seventh Modification of Wick Sheet)

As shown in FIG. 33, the first heat source region SR1, the second heat source region SR2, and the third heat source region SR3 are disposed on the wick sheet 30. In this case, any two of the first heat source region SR1, the second heat source region SR2, and the third heat source region SR3 are also connected to each other by the coupling vapor passages 51F and the coupling liquid channels 60A.

In other words, the first heat source region SR1 and the second heat source region SR2 are connected to each other by the coupling vapor passages 51F and the coupling liquid channels 60A. The branched vapor passages 51H are connected midway to one or some of these coupling vapor passages 51F. The coupling vapor passages 51F and coupling liquid channels 60A that connect the first heat source region SR1 with the second heat source region SR2 have a curved part R that is formed in a curved shape in a plan view.

The second heat source region SR2 and the third heat source region SR3 are connected to each other by the coupling vapor passages 51F and the coupling liquid channels 60A. The branched vapor passages 51H are connected midway to one or some of these coupling vapor passages 51F. The coupling vapor passages 51F and coupling liquid channels 60A that connect the second heat source region SR2 with the third heat source region SR3 have a curved part R that is formed in a curved shape in a plan view.

The third heat source region SR3 and the first heat source region SR1 are connected to each other by the coupling vapor passages 51F and the coupling liquid channels 60A. The branched vapor passages 51H are connected midway to one or some of these coupling vapor passages 51F. The coupling liquid channel 60A that connects the third heat source region SR3 with the first heat source region SR1 is connected at a connecting point 67 to another coupling liquid channel 60A that connects the first heat source region SR1 with the second heat source region SR2. In this case, the connecting point 67 is located in the first heat source region SR1; however, the configuration is not limited thereto. The connecting point 67 may be located outside the first heat source region SR1. The coupling liquid channels 60A that connect the first heat source region SR1 with the second heat source region SR2 are also connected to the coupling liquid channels 60A that connect the third heat source region SR3 with the first heat source region SR1. The coupling liquid channels 60A that connect the second heat source region SR2 with the third heat source region SR3 may also be connected to the coupling liquid channels 60A that connect the third heat source region SR3 with the first heat source region SR1.

The sole vapor passages 51G are connected to the heat source region SR2, and the sole vapor passages 51G are connected to the heat source region SR3. The sole liquid channels 60B are connected to the heat source region SR2, and the sole liquid channels 60B are connected to the heat source region SR3. The independent liquid channels 60D are disposed adjacent to the branched vapor passages 51H. The independent liquid channels 60D extend parallel to the sole liquid channels 60B extending from the heat source regions SR2, SR3. When the independent liquid channels 60D are disposed, recovery of the working liquid 2b in the plane of the wick sheet 30 is easy.

According to the present modification, any two of the first heat source region SR1, the second heat source region SR2, and the third heat source region SR3 are also connected to each other by the coupling vapor passages 51F and the coupling liquid channels 60A. Thus, even when any one or two of the three devices D1 to D3 are being driven, the working vapor 2a can be transferred to the device side not being driven. Thus, a wide range in the plane of the vapor chamber 1 can be used to transfer heat, so it is possible to cause heat from the heat sources to go around uniformly in the plane of the vapor chamber 1. Any two of the first heat source region SR1, the second heat source region SR2, and the third heat source region SR3 may also be connected by at least one coupling vapor passage 51F and do not need to be connected to each other by the coupling liquid channel 60A. Any two of the first heat source region SR1, the second heat source region SR2, and the third heat source region SR3 may also be connected by at least one coupling liquid channel 60A and do not need to be connected to each other by the coupling vapor passage 51F.

### (Eighth Modification of Wick Sheet)

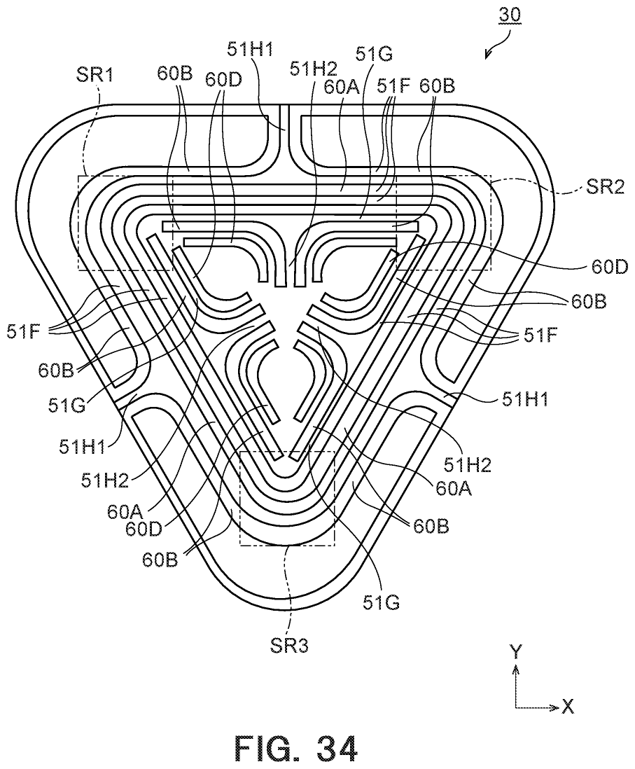

As shown in FIG. 34, the first heat source region SR1, the second heat source region SR2, and the third heat source region SR3 are disposed on the wick sheet 30. In this case, any two of the first heat source region SR1, the second heat source region SR2, and the third heat source region SR3 are also connected to each other by the coupling vapor passages 51F and the coupling liquid channels 60A.

In other words, the first heat source region SR1 and the second heat source region SR2 are connected to each other by the coupling vapor passages 51F and the coupling liquid channels 60A. A branched vapor passage 51H1 is connected midway to one of the coupling vapor passages 51F, and a branched vapor passage 51H2 is connected midway to another one of the coupling vapor passages 51F. The second heat source region SR2 and the third heat source region SR3 are connected to each other by the coupling vapor passages 51F and the coupling liquid channels 60A. A branched vapor passage 51H1 is connected midway to one of the coupling vapor passages 51F, and a branched vapor passage 51H2 is connected midway to another one of the coupling vapor passages 51F. The third heat source region SR3 and the first heat source region SR1 are connected to each other by the coupling vapor passages 51F and the coupling liquid channels 60A. A branched vapor passage 51H1 is connected midway to one of the coupling vapor passages 51F, and a branched vapor passage 51H2 is connected midway to another one of the coupling vapor passages 51F.

In FIG. 34, of the two branched vapor passages 51H1, 51H2, the branched vapor passage 51H1 extends outward in the plane direction of the wick sheet 30, and the other branched vapor passage 51H2 extends inward in the plane direction of the wick sheet 30. Thus, the working vapor 2a from the first heat source region SR1, the second heat source region SR2, and the third heat source region SR3 can be transferred to a wide range in the plane of the vapor chamber 1, so it is possible to cause heat from the heat sources to go around uniformly in the plane of the vapor chamber 1. Both the branched vapor passage 51H1 and the branched vapor passage 51H2 may be connected to one coupling vapor passage 51F.

In the first heat source region SR1, the coupling vapor passages 51F and the coupling liquid channels 60A that connect the third heat source region SR3 with the first heat source region SR1 are respectively connected to the coupling vapor passages 51F and the coupling liquid channels 60A that connect the first heat source region SR1 with the second heat source region SR2. In the second heat source region SR2, the coupling vapor passages 51F and the coupling liquid channels 60A that connect the first heat source region SR1 with the second heat source region SR2 are respectively connected to the coupling vapor passages 51F and the coupling liquid channels 60A that connect the second heat source region SR2 with the third heat source region SR3. Furthermore, in the third heat source region SR3, the coupling vapor passages 51F and the coupling liquid channels 60A that connect the second heat source region SR2 with the third heat source region SR3 are respectively connected to the coupling vapor passages 51F and the coupling liquid channels 60A that connect the third heat source region SR3 with the first heat source region SR1.

The sole vapor passage 51G is connected to each of the heat source regions SR1, SR2, SR3. The sole liquid channels 60B are connected to each of the heat source regions SR1, SR2, SR3. The independent liquid channels 60D are respectively disposed along the sole liquid channels 60B located inward in the plane direction of the wick sheet 30. When the independent liquid channels 60D are disposed, recovery of the working liquid 2b in the plane of the wick sheet 30 is easy.

The wick sheet 30 may have a planar shape according to the shapes of the heat source regions SR1, SR2, SR3 and may, for example, have a substantially triangular shape (a regular triangular shape with a rounded corner in FIG. 34) in a plan view. The center of the first heat source region SR1, the center of the second heat source region SR2, and the center of the third heat source region SR3 may be respectively disposed at positions corresponding to the vertexes of the triangle. The wick sheet 30 is not limited to a triangular shape and may be a selected shape, such as a rectangular shape, a circular shape, an elliptical shape, an L-shape, a T-shape, and a U-shape. The coupling vapor passages 51F, the sole vapor passages 51G, the branched vapor passages 51H1, 51H2, the coupling liquid channels 60A, the sole liquid channels 60B, and/or the independent liquid channels 60D of the configuration shown in FIG. 34 may be disposed in the wick sheet 30 having a selected shape.

According to the present modification, any two of the first heat source region SR1, the second heat source region SR2, and the third heat source region SR3 are also connected to each other by the coupling vapor passages 51F and the coupling liquid channels 60A. Thus, even when any one or two of the three devices D1 to D3 are being driven, the working vapor 2a can be transferred to the device side not being driven. Thus, a wide range in the plane of the vapor chamber 1 can be used to transfer heat, so it is possible to cause heat from the heat sources to go around uniformly in the plane of the vapor chamber 1.

### (Ninth Modification of Wick Sheet)

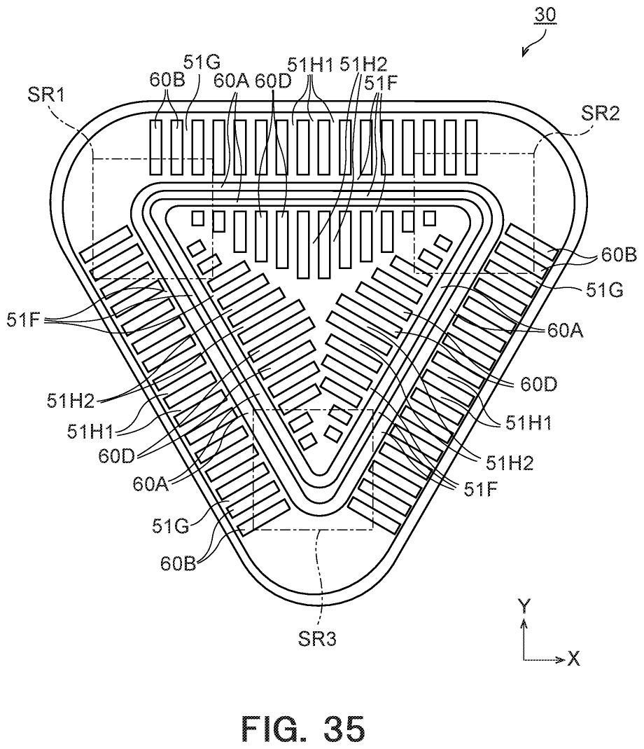

As shown in FIG. 35, the first heat source region SR1, the second heat source region SR2, and the third heat source region SR3 are disposed on the wick sheet 30. In this case, any two of the first heat source region SR1, the second heat source region SR2, and the third heat source region SR3 are also connected to each other by the coupling vapor passages 51F and the coupling liquid channels 60A.

In other words, the first heat source region SR1 and the second heat source region SR2 are connected to each other by the coupling vapor passages 51F and the coupling liquid channels 60A. A plurality of branched vapor passages 51H1 is connected midway to one of the coupling vapor passages 51F, and a plurality of branched vapor passages 51H2 is connected midway to another one of the coupling vapor passages 51F. The second heat source region SR2 and the third heat source region SR3 are connected to each other by the coupling vapor passages 51F and the coupling liquid channels 60A. A plurality of branched vapor passages 51H1 is connected midway to one of the coupling vapor passages 51F, and a plurality of branched vapor passages 51H2 is connected midway to another one of the coupling vapor passages 51F. The third heat source region SR3 and the first heat source region SR1 are connected to each other by the coupling vapor passages 51F and the coupling liquid channels 60A. A plurality of branched vapor passages 51H1 is connected midway to one of the coupling vapor passages 51F, and a plurality of branched vapor passages 51H2 is connected midway to another one of the coupling vapor passages 51F.

In FIG. 35, of the set of branched vapor passages 51H1 and the set of branched vapor passages 51H2, the branched vapor passages 51H1 extend outward in the plane direction of the wick sheet 30, and the other branched vapor passages 51H2 extend inward in the plane direction of the wick sheet 30. Thus, the working vapor 2a from the first heat source region SR1, the second heat source region SR2, and the third heat source region SR3 can be transferred to a wide range in the plane of the vapor chamber 1, so it is possible to cause heat from the heat sources to go around uniformly in the plane of the vapor chamber 1. Both the set of branched vapor passages 51H1 and the set of branched vapor passages 51H2 may be connected to one coupling vapor passage 51F.

The sole vapor passages 51G are connected to each of the heat source regions SR1, SR2, SR3. The sole liquid channels 60B are connected to each of the heat source regions SR1, SR2, SR3. The independent liquid channels 60D are disposed adjacent to the branched vapor passages 51H1, 51H2. The independent liquid channels 60D extend parallel to the sole liquid channels 60B respectively extending from the heat source regions SR1, SR2, SR3. When the independent liquid channels 60D are disposed, recovery of the working liquid 2b in the plane of the wick sheet 30 is easy.

The wick sheet 30 may have a planar shape according to the shapes of the heat source regions SR1, SR2, SR3 and may, for example, have a substantially triangular shape (a regular triangular shape with a rounded corner in FIG. 35) in a plan view. The center of the first heat source region SR1, the center of the second heat source region SR2, and the center of the third heat source region SR3 may be respectively disposed at positions corresponding to the vertexes of the triangle. The wick sheet 30 is not limited to a triangular shape and may be a selected shape, such as a rectangular shape, a circular shape, an elliptical shape, an L-shape, a T-shape, and a U-shape. The coupling vapor passages 51F, the sole vapor passages 51G, the branched vapor passages 51H1, 51H2, the coupling liquid channels 60A, the sole liquid channels 60B, and/or the independent liquid channels 60D of the configuration shown in FIG. 35 may be disposed in the wick sheet 30 having a selected shape.

According to the present modification, any two of the first heat source region SR1, the second heat source region SR2, and the third heat source region SR3 are also connected to each other by the coupling vapor passages 51F and the coupling liquid channels 60A. Thus, even when any one or two of the three devices D1 to D3 are being driven, the working vapor 2a can be transferred to the device side not being driven. Thus, a wide range in the plane of the vapor chamber 1 can be used to transfer heat, so it is possible to cause heat from the heat source to go around uniformly in the plane of the vapor chamber 1.

### (Modifications of Vapor Chamber)

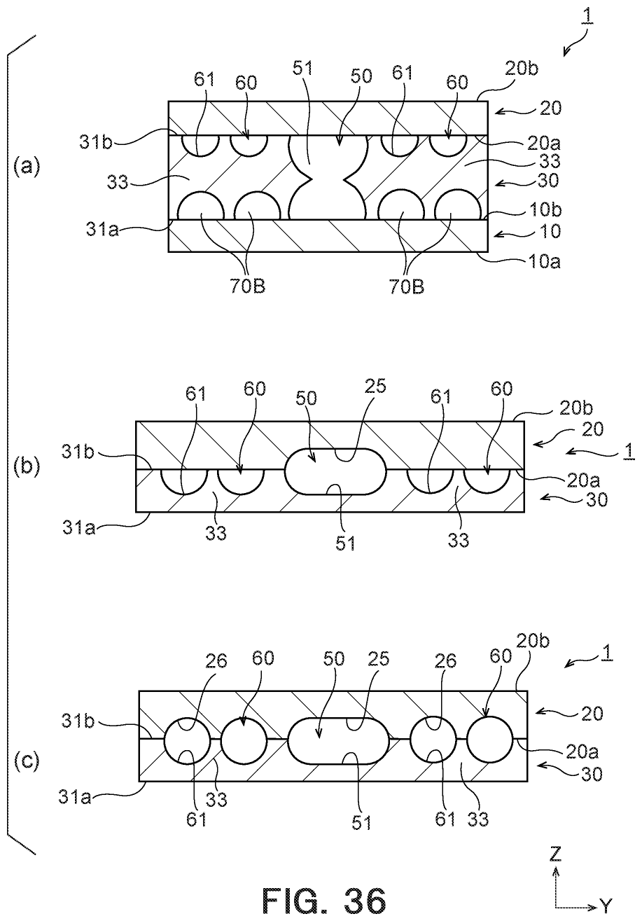

Next, various modifications of the vapor chamber will be described with reference to FIGS. 36(a) to 36(c). FIGS. 36(a) to 36(c) are sectional views respectively showing the vapor chambers 1 according to the modifications. In FIGS. 36(a) to 36(c), like reference signs are assigned to the same portions as those of the embodiment shown in FIGS. 19 to 35, and the detailed description is omitted.

As shown in FIG. 36(a), liquid storage portions 70B that mainly store the working liquid 2b may be provided on the first main body surface 31a of the wick sheet 30. The liquid storage portions 70B communicate with the vapor channel 50 and also communicate with the liquid channels 60 via the vapor channel 50. The liquid storage portions 70B may be disposed in the heat source regions SR1, SR2 in a plan view. Thus, while the devices D1, D2 stop generating heat, the working liquid 2b can be stored not only in the liquid channels 60 but also in the liquid storage portions 70B in a distributed manner. Therefore, even when the working liquid 2b in the liquid channels 60 freezes to expand in a temperature environment lower than the freezing point of the working liquid 2b, it is possible to reduce expansion force applied to the upper sheet 20 and the lower sheet 10, so it is possible to suppress a deformation of the upper sheet 20 and the lower sheet 10. As a result, it is possible to suppress a deformation of the vapor chamber 1, so it is possible to suppress a decrease in the performance of the vapor chamber 1.

As shown in FIGS. 36(b) and 36(c), the vapor chamber 1 may be made up of two-layer sheets. In other words, the vapor chamber 1 includes the wick sheet 30, and the upper sheet (sheet) 20 laminated on the wick sheet 30. The vapor passage 51 of the wick sheet 30 is formed in a recessed shape on the first main body surface 31a side of the wick sheet 30, and is formed in a groove without extending through the wick sheet 30.

In FIGS. 36(b) and 36(c), the upper sheet 20 has an upper vapor channel recess 25 provided on the first upper sheet surface 20a. The upper vapor channel recess 25 is formed in a recessed shape on the first upper sheet surface 20a side of the upper sheet 20 and is formed in a groove without extending through the upper sheet 20. The upper vapor channel recess 25 is integrated with the vapor passage 51 of the wick sheet 30 to form the vapor channel 50.

In FIG. 36(c), the upper sheet 20 has upper liquid channel recesses 26 provided on the first upper sheet surface 20a. The upper liquid channel recesses 26 are formed in a recessed shape on the first upper sheet surface 20a side of the upper sheet 20 and are formed in a groove without extending through the upper sheet 20. The upper liquid channel recesses 26 are respectively integrated with the liquid channel main stream grooves 61 and liquid channel communication grooves 65 of the wick sheet 30 to form the liquid channels 60. In FIG. 36(b), the upper liquid channel recesses 26 are not provided, and the liquid channels 60 are present only in the wick sheet 30.

Alternatively, although not shown in the drawing, the vapor chamber 1 just needs to have a vapor passage and a liquid channel. The vapor chamber 1 may be made up of four or more-layer sheet members or may be the one not formed by laminating a plurality of sheet members.

The present disclosure is not limited to the embodiments and the modifications, and component elements may be modified without departing from the purport of the present disclosure. Various inventions may be provided by appropriate combinations of the plurality of component elements described in the embodiments and the modifications. Some component elements may be deleted from all the component elements described in the embodiments and the modifications.

1. A wick sheet for a vapor chamber, the wick sheet comprising:
a first main body surface;
a second main body surface on an opposite side to the first main body surface;
a frame; and
a plurality of lands provided inside the frame so as to be spaced apart from each other, wherein
a vapor passage extending through from the first main body surface to the second main body surface and through which vapor of a working fluid passes is formed between the frame and the land or between the plurality of lands,
a liquid channel that communicates with the vapor passage and through which the liquid working fluid passes is formed on the second main body surface side of at least one of the lands, and
an end of the vapor passage in an extension direction is in contact with at least one of the plurality of lands, and a first main body surface-side channel that communicates with the vapor passage is formed on the first main body surface side of the land in a connection region in which the end of the vapor passage in the extension direction is in contact with the land.

2. The wick sheet according to claim 1, wherein another vapor passage is present on an opposite side of the connection region to a side where the end of the vapor passage in the extension direction is in contact with the land.

3. The wick sheet according to claim 1, wherein a vaporization region in which a heat source is disposed is present on the wick sheet, and the first main body surface-side channel is continuously formed up to the vaporization region along the land.

4. The wick sheet according to claim 1, wherein the first main body surface-side channel is also formed in another one of the lands extending along the vapor passage.

5. The wick sheet according to claim 1, wherein, in the connection region in which the end of the vapor passage in the extension direction is in contact with the land, the land and the vapor passage intersect at an angle not a right angle in a plan view.

6. The wick sheet according to claim 1, wherein the connection region is located at a part where the land is curved.

7. The wick sheet according to claim 1, wherein at least two of the plurality of lands merge, and the end of the vapor passage in the extension direction is in contact with the land at the merged part.

8. The wick sheet according to claim 1, wherein, at a location where the end of the vapor passage in the extension direction is in contact with the land, the vapor passage and the land are orthogonal to each other in a plan view.

9. The wick sheet according to claim 1, wherein the connection region is thinned from the first main body surface side.

10. A wick sheet for a vapor chamber, the wick sheet comprising:
a first main body surface;
a second main body surface on an opposite side to the first main body surface;
a frame; and
a plurality of lands provided inside the frame so as to be spaced apart from each other, wherein
a through-space extending through from the first main body surface to the second main body surface is formed between the frame and the land or between the plurality of lands,
a second main body surface groove that communicates with the through-space is formed on the second main body surface side of at least one of the lands, and
an end of the through-space in an extension direction is in contact with at least one of the plurality of lands, and a first main body surface-side groove that communicates with the through-space is formed on the first main body surface side of the land in a connection region in which the end of the through-space in the extension direction is in contact with the land.

11-21. (canceled)

22. The wick sheet according to claim 9, wherein the first main body surface-side channel comprises a plurality of first main body surface-side main stream grooves and a plurality of protrusion arrays.

23. The wick sheet according to claim 22, wherein the first main body surface-side main stream grooves and the protrusion arrays extend in a flow direction of the vapor of the working fluid.

24. The wick sheet according to claim 9, wherein the first main body surface-side channel comprises a first main body surface-side main stream groove and a pair of protrusions located at both ends of the first main body surface-side main stream groove in the width direction.

25. The wick sheet according to claim 9, wherein the first main body surface-side channel comprises a flat surface.

26. The wick sheet according to claim 9, wherein at least two lands of the plurality of lands are connected to each other, and
the first main body surface-side channel is formed at a connecting portion of the at least two connected lands.

27. The wick sheet according to claim 26, wherein another first main body surface-side channel, not thinned from the first main body surface side, is formed at a position adjacent to the first main body surface-side channel.

28. The wick sheet according to claim 9, wherein
a vaporization region, in which a heat source is disposed, is present on the wick sheet,
another first main body surface-side channel, not thinned from the first main body surface side, is formed at a position adjacent to the connection region, and
the another first main body surface-side channel, not thinned from the first main body surface side, is continuously formed up to the vaporization region along the land.

29. A vapor chamber filled with a working fluid, the vapor chamber comprising:
a first sheet;
a second sheet; and
the wick sheet according to claim 1, interposed between the first sheet and the second sheet.

30. An electronic apparatus comprising:
a housing;
a device accommodated in the housing; and
the vapor chamber according to claim 29, being in thermal contact with the device.

31. A vapor chamber filled with a working fluid, the vapor chamber comprising:
a first sheet;
a second sheet; and
the wick sheet according to claim 10, interposed between the first sheet and the second sheet.

32. An electronic apparatus comprising:
a housing;
a device accommodated in the housing; and
the vapor chamber according to claim 31, being in thermal contact with the device.
